(19) United States
(12) Patent Application Publication
(10) Pub. No.: US 2026/0262315 A1
(43) Pub. Date: Sep. 3, 2026

(54) PHOTODETECTOR AND METHOD OF MANUFACTURING THE SAME

(71) Applicant: SONY SEMICONDUCTOR SOLUTIONS CORPORATION, KANAGAWA (JP)

(72) Inventors: TOMOKI MIKURIYA, KUMAMOTO (JP); TETSUHIRO IWASHITA, KUMAMOTO (JP)

(21) Appl. No.: 19/159,628

(22) PCT Filed: Feb. 22, 2024
(86) PCT No.: PCT/JP2024/006650

§ 371 Date: Aug. 26, 2025

(30) Foreign Application Priority Data
Mar. 22, 2023 (JP) 2023-045365

(51) Int. Cl. H10F 39/00

(52) U.S. Cl. CPC H10F 39/807; H10F 39/014; H10F 39/024; H10F 39/805

(57) ABSTRACT

A photodetector capable of suppressing a decrease in yield and a method of manufacturing the same are provided. The photodetector includes a semiconductor substrate having a first surface, and a second surface located on a side opposite to the first surface, a plurality of pixels provided on the semiconductor substrate and having photoelectric conversion elements, an inter-pixel isolation part provided between one and the other of adjacent pixels among the plurality of pixels and penetrating between the first surface and the second surface of the semiconductor substrate, and a surrounding part provided on the first surface side of the semiconductor substrate and surrounding an end of the inter-pixel isolation part.

The surrounding part is made of a material different from a material of the semiconductor substrate.

### TECHNICAL FIELD

The present disclosure relates to a photodetector and a method of manufacturing the same.

### BACKGROUND ART

As an inter-pixel isolation part of a pixel having a photoelectric conversion element, an inter-pixel isolation part penetrating a semiconductor substrate in a depth direction is known (refer to PTL 1, for example).

### CITATION LIST

### Patent Literature

### PTL 1

JP 2020-013909 A

### SUMMARY

### Technical Problem

In the process of forming the inter-pixel isolation part penetrating the semiconductor substrate, the semiconductor substrate is etched using a mask to form a trench penetrating the semiconductor substrate, and after the trench is formed, the mask is removed by wet etching. If the chemical solution penetrates through the trench to the opposite side to the mask formation surface of the semiconductor substrate at the time of removing the mask, the insulating film covering the opposite side to the mask formation surface is eroded by the chemical solution, and the yield of the photodetector may be lowered.

The present disclosure has been devised in consideration of the above circumstances, and an object of the present disclosure is to provide a photodetector capable of suppressing a decrease in yield and a method of manufacturing the same.

### Solution to Problem

A photodetector according to one aspect of the present disclosure includes a semiconductor substrate having a first surface, and a second surface located on a side opposite to the first surface, a plurality of pixels provided on the semiconductor substrate and having photoelectric conversion elements, an inter-pixel isolation part provided between one and the other of adjacent pixels among the plurality of pixels and penetrating between the first surface and the second surface of the semiconductor substrate, and a surrounding part provided on the first surface side of the semiconductor substrate and surrounding an end of the inter-pixel isolation part. The surrounding part is made of a material different from a material of the semiconductor substrate.

According to this, even if a chemical solution enters from the second surface side of the semiconductor substrate through the trench to the first surface side at the time of removing a mask used at the time of forming the trench for the inter-pixel isolation part by wet etching, the surrounding part can prevent the chemical solution from contacting an insulating film covering the first surface side. Accordingly, since the insulating film covering the first surface side of the semiconductor substrate can be prevented from being eroded by the chemical solution for removing the mask, a decrease in the yield of the photodetector can be suppressed.

A method of manufacturing a photodetector according to one aspect of the present disclosure includes a process of forming a first material film on a first surface side of a semiconductor substrate having a first surface and a second surface located on a side opposite to the first surface and provided with a plurality of pixels having photoelectric conversion elements, and covering a predetermined region for isolating adjacent pixels from each other among the plurality of pixels with the first material film from the first surface side, a process of forming a second material film on a side opposite to the predetermined region with the first material film interposed between the second material film and the predetermined region, a process of forming a third material film on a side opposite to the first material film with the second material film interposed between the third material film and the first material film, and surrounding the second material film with the first material film and the third material film, a process of forming a mask having a shape of exposing the predetermined region and covering a region other than the predetermined region on the second surface side, a process of forming a trench penetrating the semiconductor substrate and the first material film by etching the predetermined region exposed through the mask from the second surface side using the second material film as an etching stopper, and a process of removing the mask by wet etching after forming the trench. A chemical solution that easily etches the mask and the second material film and hardly etches the first material film and the third material film is used for the wet etching.

According to this, even if the chemical solution for removing the mask enters from the second surface side of the semiconductor substrate through the trench to the first surface side in the process of removing the mask, contact between the chemical solution and the insulating film covering the first surface side of the semiconductor substrate can be prevented by the surrounding part. Accordingly, since the insulating film covering the first surface side of the semiconductor substrate can be prevented from being eroded by the chemical solution for removing the mask, a decrease in the yield of the photodetector can be suppressed.

### BRIEF DESCRIPTION OF DRAWINGS

FIG. 1 is a cross-sectional view showing a configuration example of a photodetector having an inter-pixel isolation part according to an embodiment of the present disclosure.

FIG. 2 is a cross-sectional view showing a method of manufacturing the photodetector according to an embodiment of the present disclosure in the order of processes.

FIG. 3 is a cross-sectional view showing the method of manufacturing the photodetector according to the embodiment of the present disclosure in the order of processes.

FIG. 4 is a cross-sectional view showing the method of manufacturing the photodetector according to the embodiment of the present disclosure in the order of processes.

FIG. 5 is a cross-sectional view showing the method of manufacturing the photodetector according to the embodiment of the present disclosure in the order of processes.

FIG. 6 is a cross-sectional view showing a photodetector according to modified example 1 of the embodiment of the present disclosure.

FIG. 7 is a cross-sectional view showing a photodetector according to modified example 2-1 of the embodiment of the present disclosure.

FIG. 8 is a cross-sectional view showing a photodetector according to modified example 2-2 of the embodiment of the present disclosure.

FIG. 9 is a cross-sectional view showing a photodetector according to modified example 3 of the embodiment of the present disclosure.

FIG. 10 is a cross-sectional view showing a photodetector according to modified example 4-1 of the embodiment of the present disclosure.

FIG. 11 is a cross-sectional view showing a photodetector according to modified example 4-2 of the embodiment of the present disclosure.

FIG. 12 is a cross-sectional view showing a photodetector according to modified example 5-1 of the embodiment of the present disclosure.

FIG. 13 is a cross-sectional view showing a photodetector according to modified example 5-2 of the embodiment of the present disclosure.

FIG. 14 is a cross-sectional view showing a photodetector according to modified example 6-1 of the embodiment of the present disclosure.

FIG. 15 is a cross-sectional view showing a photodetector according to modified example 6-2 of the embodiment of the present disclosure.

FIG. 16 is a diagram showing a configuration of an imaging element according to application example 1-1 of the present disclosure.

FIG. 17 is a cross-sectional view showing a configuration of a pixel array according to application example 1-1 of the present disclosure.

FIG. 18 is a cross-sectional view showing a configuration of a pixel array of a light-receiving element according to application example 1-2 of the present disclosure.

FIG. 19 is a cross-sectional view showing a configuration of a pixel array of a light-receiving element according to application example 1-3 of the present disclosure.

FIG. 20 is a cross-sectional view showing a configuration of a sensor chip according to application example 2-1 of the present disclosure.

FIG. 21 is a cross-sectional view showing a configuration of a backside illumination type pixel according to application example 2-2 of the present disclosure.

FIG. 22 is a cross-sectional view showing a configuration of pixels in an imaging device according to application example 3-1 of the present disclosure.

FIG. 23 is a cross-sectional view showing a configuration of a pixel array of an imaging device according to application example 3-2 of the present disclosure.

### DESCRIPTION OF EMBODIMENTS

An embodiment of the present disclosure will be described below with reference to the drawings. In descriptions of the drawings referred to in the following description, same or similar portions will be denoted by same or similar reference signs. However, it should be noted that the drawings are schematic, and the relationships between thicknesses and planar dimensions, ratios of thicknesses of respective layers, and the like are different from actual ones. Therefore, specific thicknesses and dimensions should be determined in light of the following descriptions. In addition, it goes without saying that the drawings include portions having different dimensional relationships and ratios.

In addition, it is to be understood that definitions of directions such as up-down in the following descriptions are merely definitions provided for the sake of brevity and are not intended to limit the technical spirit of the present disclosure. For example, it is obvious that when an object is observed after being rotated by 90 degrees, up-down is converted into and interpreted as left right, and when an object is observed after being rotated by 180 degrees, up-down is interpreted as being inverted.

### Embodiment

### (Structure)

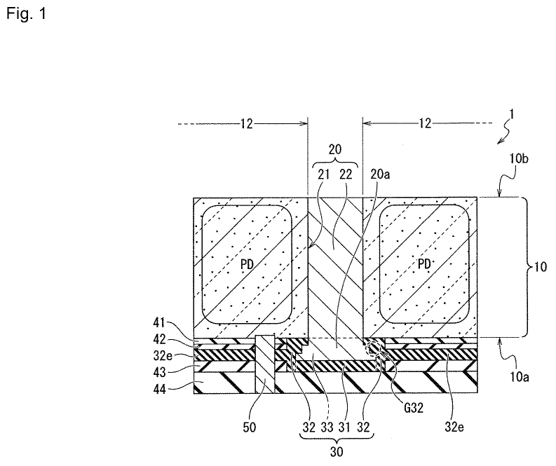

FIG. 1 is a cross-sectional view showing a configuration example of a photodetector 1 having an inter-pixel isolation part 20 according to an embodiment of the present disclosure. As shown in FIG. 1, the photodetector 1 includes a semiconductor substrate 10, a plurality of pixels 12 provided on the semiconductor substrate 10, the inter-pixel isolation part 20 provided on the semiconductor substrate 10, and a surrounding part 30 provided on the side of the front surface 10a of the semiconductor substrate 10 and surrounding an end 20a of the inter-pixel isolation part 20.

The semiconductor substrate 10 has the front surface (a lower surface in FIG. 1; an example of a “first surface” in the present disclosure) 10a and a rear surface 10b (an upper surface in FIG. 1; an example of a “second surface” in the present disclosure) located on the opposite side to the front surface. The semiconductor substrate 10 is made of, for example, single crystal silicon (Si).

Each of the plurality of pixels 12 provided on the semiconductor substrate 10 is composed of a photodiode PD (an example of a “photoelectric conversion element” in the present disclosure) and a plurality of pixel transistors. The photodiode PD is formed to extend over the entire thickness of the semiconductor substrate 10, and is configured as a pn-junction photodiode composed of an n-type semiconductor region and a p-type semiconductor region, for example. The plurality of pixels 12 are arranged in a matrix when viewed from a plane in the thickness direction of the semiconductor substrate 10.

The inter-pixel isolation part 20 is provided between one and the other of adjacent pixels 12 among the plurality of pixels 12. The inter-pixel isolation part 20 penetrates between the rear surface 10b and the front surface 10a of the semiconductor substrate 10. For example, the inter-pixel isolation part 20 has a trench 21 penetrating between the rear surface 10b and the front surface 10a of the semiconductor substrate 10, and an isolation film 22 embedded within the trench 21. The isolation film 22 is a film for electrically and optically isolating the adjacent pixels 12 and is made of, for example, silicon oxide (SiO), polysilicon (Polu-Si), tungsten (W), aluminum (Al), or copper (Cu), or a plurality of films containing one or more thereof.

Since the inter-pixel isolation part 20 penetrates the semiconductor substrate 10, it may be called full trench isolation (FTI). Further, as will be described later, the inter-pixel isolation part 20 is formed from the side of the rear surface 10b of the semiconductor substrate 10, and thus it may be called reverse full trench isolation (RFTI).

The surrounding part 30 is provided on the side of the front surface 10a of the semiconductor substrate 10. The surrounding part 30 is made of a material different from that of the semiconductor substrate 10. For example, the surrounding part 30 is made of silicon nitride (SiN) or silicon nitride containing at least one of oxygen and carbon (SiON, SiCN). The surrounding part 30 may be formed by laminating two or more films of an SiN film, an SiON film, and an SiCN film.

As shown in FIG. 1, the surrounding part 30 has a bottom portion 31 and a side portion 32. The bottom portion 31 is disposed at a position away from the front surface 10a of the semiconductor substrate 10. The bottom portion 31 faces an end 20a located on the side of the front surface 10a (lower side in FIG. 1) between both ends of the inter-pixel isolation part 20 in the thickness direction of the semiconductor substrate 10. The side portion 32 connects the front surface 10a of the semiconductor substrate 10 to the bottom portion 31.

Accordingly, the shape of the surrounding part 30 is recessed with respect to the end 20a of the inter-pixel isolation part 20. The end 20a of the inter-pixel isolation part 20 is disposed in a space 33 inside the surrounding part 30 and surrounded from the outside by the surrounding part 30. The end 20a of the inter-pixel isolation part 20 is isolated from insulating films 41, 42, 43, and 44 which will be described later by the surrounding part 30 without any gap.

For example, the side portion 32 has an extension part 32e extending in a direction away from the inter-pixel isolation part 20 along the front surface 10a of the semiconductor substrate 10. Further, a step portion G32 is provided on the inner surface of the side portion 32.

As shown in FIG. 1, insulating films adjacent to the surrounding part 30 from the outside of the surrounding part 30 are provided on the side of the front surface 10a of the semiconductor substrate 10. For example, on the side of the front surface 10a of the semiconductor substrate 10, insulating films 41, 42, 43, and 44 adjacent to the surrounding part 30 are provided from the outside of the surrounding part 30. The insulating films 41 and 42 are provided between the front surface 10a of the semiconductor substrate 10 and the extension part 32e. Further, the insulating films 43 and 44 are provided on the opposite side of the insulating films 41 and 42 with the extension part 32e interposed therebetween. The insulating films 41, 42, 43, and 44 are formed in this order from the front surface 10a of the semiconductor substrate 10. The film formation direction is the downward direction in FIG. 1. The insulating films 41, 42, 43, and 44 are made of materials different from those of the semiconductor substrate 10 and the surrounding part 30, and are made of, for example, silicon oxide (SiO).

For example, the insulating film 41 is used as a gate insulating film of a pixel transistor (not shown) provided on the semiconductor substrate 10. The insulating film 42 is used as a protective film for protecting the gate electrode of the pixel transistor. The insulating films 43 and 44 are used as interlayer insulating films. However, the respective uses of the insulating films 41, 42, 43, and 44 are not limited to the above, and they may be formed for other uses. In this example, the insulating films 41, 42, 43, and 44 are examples of “insulating films” in the present disclosure. Further, among these insulating films, the insulating films 41 and 42 are an example of a “first insulating film” in the present disclosure.

In addition, the photodetector 1 further includes a via 50 connected to the front surface 10a of the semiconductor substrate 10. The via 50 penetrates through the insulating films 41, 42, 43, and 44 and the extension part 32e. For example, charges generated by photoelectric conversion in the photodiode PD are transferred to a read circuit provided on the side of the front surface 10a of the semiconductor substrate 10 via the via 50.

### (Manufacturing Method)

Next, a method of manufacturing the inter-pixel isolation part 20 and the surrounding part 30 of the photodetector 1 shown in FIG. 1 will be described. The photodetector 1 is manufactured using various apparatuses such as a resist coating apparatus, an exposure apparatus, an etching apparatus, and a film forming apparatus. Hereinafter, these apparatuses will be collectively referred to as a manufacturing apparatus.

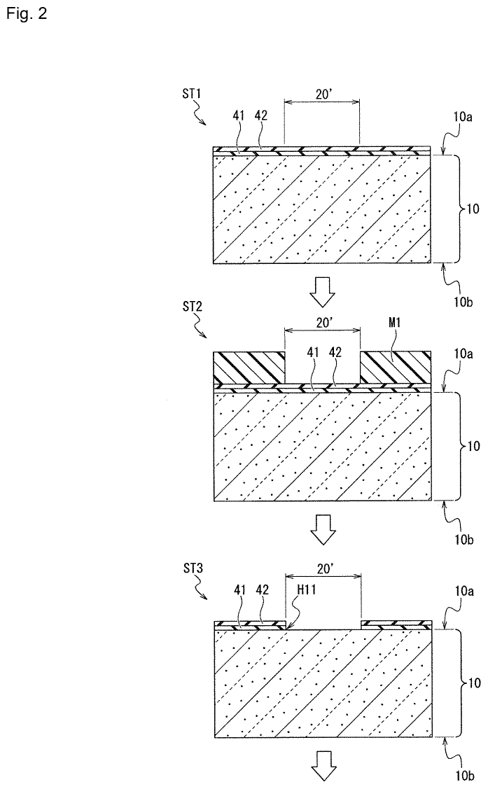

FIG. 2 to FIG. 5 are cross-sectional views showing the method of manufacturing the photodetector 1 according to an embodiment of the present disclosure in the order of processes. As shown in step ST1 in FIG. 2, the manufacturing apparatus prepares the semiconductor substrate 10 on which the insulating films 41 and 42 are formed in this order on the front surface 10a. The insulating films 41 and 42 cover a predetermined region 20′ where the inter-pixel isolation part 20 (refer to FIG. 1) for isolating adjacent pixels 12 from each other among the plurality of pixels 12 will be formed. The semiconductor substrate 10 is made of, for example, single crystal silicon. The insulating films 41 and 42 are made of, for example, SiO. The insulating films 41 and 42 have a total thickness of, for example, 11 nm.

In this example, the width of the predetermined region 20′ is set to be wider than the width of the inter-pixel isolation part 20 to be finally formed. This is for the purpose of ensuring a margin for misalignment in a plurality of mask forming processes which will be described below. Further, in this example, annealing processing for forming a source and a drain of a pixel transistor may be performed in step ST1 in FIG. 2.

Next, as shown in step ST2 of FIG. 2, the manufacturing apparatus forms a mask M1 on the insulating film 42. The mask M1 has a shape that exposes the predetermined region 20′ and covers the other regions. The mask M1 is made of, for example, a photoresist.

Next, the manufacturing apparatus performs etching processing on side of the front surface 10a of the semiconductor substrate 10 on which the mask M1 is formed to remove the insulating films 42 and 41 in this order from the predetermined region 20′ exposed through the mask M1. Accordingly, as shown in step ST3 in FIG. 2, an opening H11 having the front surface 10a of the semiconductor substrate 10 as a bottom surface is formed in the predetermined region 20′.

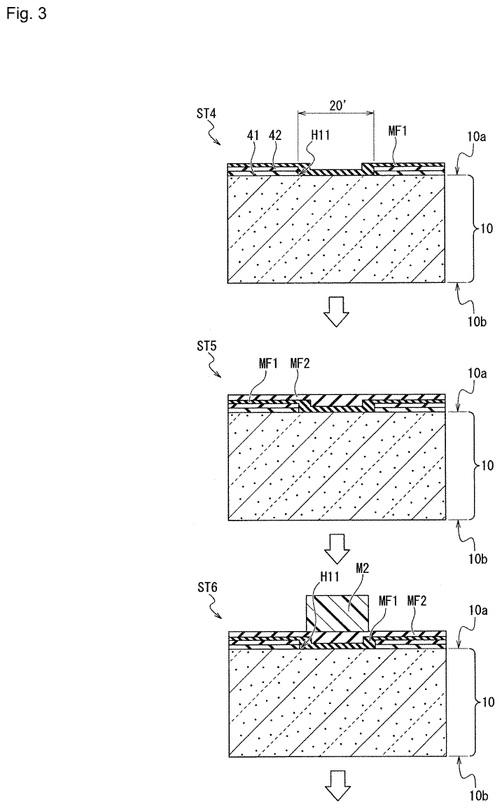

Next, as shown in step ST4 of FIG. 3, the manufacturing apparatus forms a first material film MF1 on the side of the front surface 10a of the semiconductor substrate 10 to fill the opening H11. The first material film MF1 is a part of films constituting the surrounding part 30 (refer to FIG. 1), and is made of, for example, SiN. The first material film MF1 has a film thickness of 20 nm, for example.

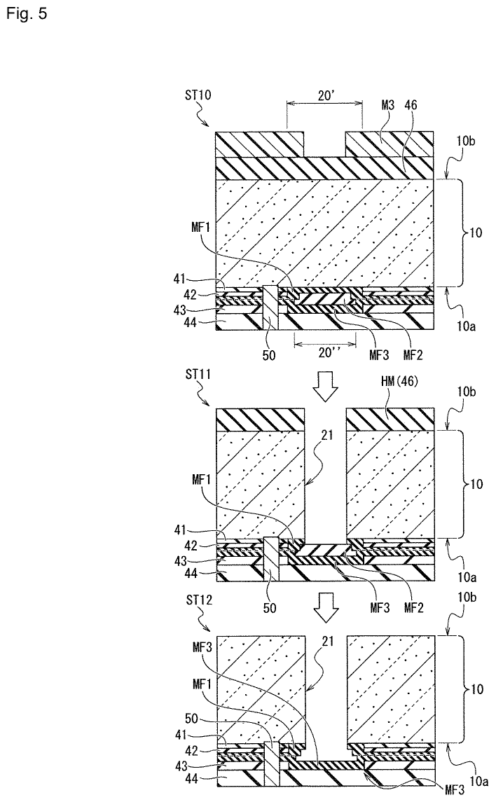

Next, as shown in step ST5 of FIG. 3, the manufacturing apparatus forms a second material film MF2 on the first material film MF1. The second material film MF2 is a film that serves as an etching stopper in a process of forming a trench 21 which will be described later (refer to step ST11 of FIG. 5), and is made of, for example, SiO. The second material film MF2 has a film thickness of 20 nm, for example.

Next, as shown in step ST6 of FIG. 3, the manufacturing apparatus forms a mask M2 on the second material film MF2. The mask M2 has a shape that covers the top portion of the opening H11 and exposes other regions. The mask M2 is made of, for example, a photoresist. The width of the mask M2 may be less than the width of the opening H11 in consideration of the margin for misalignment of the mask M2 with respect to the opening H11.

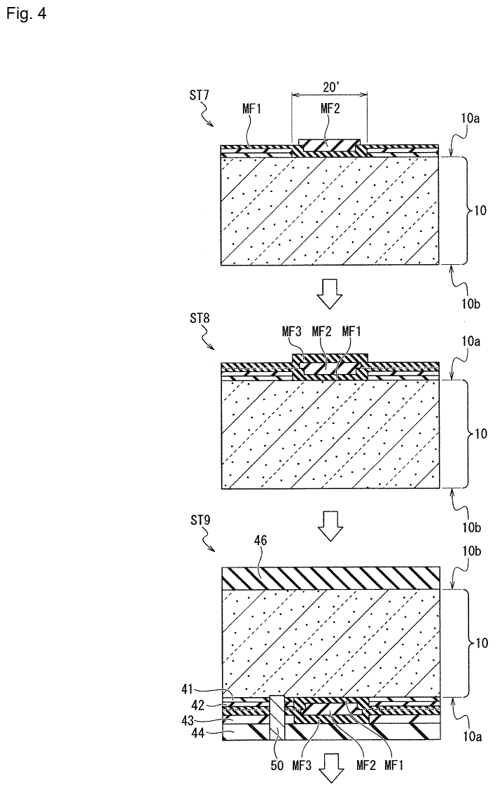

Next, the manufacturing apparatus performs etching processing on the side of the front surface 10a of the semiconductor substrate 10 on which the mask M2 is formed to remove a portion of the second material film MF2 that is exposed through the mask M2. As a result, as shown in step ST7 of FIG. 4, the second material film MF2 is disposed above the opening H11 (that is, a region overlapping the opening H11 in the thickness direction of the semiconductor substrate 10) and is not disposed in other regions.

Next, as shown in step ST8 of FIG. 4, the manufacturing apparatus forms a third material film MF3 on the side of the front surface 10a of the semiconductor substrate 10 to envelop the second material film MF2 from above and below with the first material film MF1 and the third material film MF3. The third material film MF3 is a part of the film constituting the above-mentioned surrounding part 30 (refer to FIG. 1), and is made of, for example, SiN. The third material film MF3 has a film thickness of 20 nm, for example.

In the process of forming the inter-pixel isolation part 20, processing performed on the side of the front surface 10a of the semiconductor substrate 10 is as above. Thereafter, as shown in step ST9 of FIG. 4, processing is performed on the side of the rear surface 10b of the semiconductor substrate 10 to form the inter-pixel isolation part 20. Before processing performed on the side of the rear surface 10b of the semiconductor substrate 10, the insulating films 43 and 44 may be formed on the side of the front surface 10a of the semiconductor substrate 10 or the via 50 may be formed. For example, after the third material film MF3 is formed, the manufacturing apparatus forms the insulating film 43 and performs chemical mechanical polishing (CMP) processing on the insulating film 43 to flatten the surface of the insulating film 43. The insulating film 43 is made of, for example, SiO.

Next, the manufacturing apparatus forms the insulating film 44 on the flattened insulating film 43. The insulating film 44 is made of, for example, SiO. Thereafter, the manufacturing apparatus forms the via 50 penetrating through the insulating films 44 and 43, the third material film MF3, the first material film MF1, and the insulating films 42 and 41 to be connected to the front surface 10a. Such processing may be performed on the side of the front surface 10a of the semiconductor substrate 10.

As shown in step ST9 of FIG. 4, the manufacturing apparatus forms an insulating film 46 on the side of the rear surface 10b of the semiconductor substrate 10 after forming the via 50, for example. The insulating film 46 is, for example, a SiO film.

Next, as shown in step ST10 of FIG. 5, the manufacturing apparatus forms a mask M3 on the insulating film 46. The mask M3 has a shape that exposes the predetermined region 20′ and covers other regions. For example, in the thickness direction of the semiconductor substrate 10, a region where the third material film MF3, the second material film MF2, and the first material film MF1 overlap (hereinafter referred to as an overlap region) 20″ is located inside the predetermined region 20′. The mask M3 has a shape that exposes the overlap region 20″ and covers other regions.

Next, as shown in a step ST11 of FIG. 5, the manufacturing apparatus performs etching processing on the insulating film 46 on which the mask M3 is formed to remove a portion of the insulating film 46 exposed through the mask M3. Accordingly, as shown in step ST11 of FIG. 5, the manufacturing apparatus forms a hard mask HM made of the insulating film 46.

Next, the manufacturing apparatus dry-etches a region of the semiconductor substrate 10, which is exposed through the hard mask HM, on the side of the rear surface 10b of the semiconductor substrate 10. According to this dry etching, the trench 21 which penetrates the semiconductor substrate 10 and the first material film MF1 and has the second material film MF2 as a bottom surface is formed.

Next, as shown in step ST12 of FIG. 5, the manufacturing apparatus performs wet etching on the semiconductor substrate 10 in which the trench 21 is formed to remove the hard mask HM from the side of the rear surface 10b of the semiconductor substrate 10. For example, since the hard mask HM is made of SiO, a chemical solution containing hydrofluoric acid (HF) is used for wet etching. Further, the second material film MF2 located at the bottom of the trench 21 is also made of SiO, similar to the hard mask HM. Accordingly, the second material film MF2 is also removed by wet etching using the chemical solution containing HF, together with the hard mask HM. On the other hand, the first material film MF1 and the third material film MF3 are made of SiN and thus are not etched by wet etching using the chemical solution containing HF. Accordingly, the surrounding part 30 composed of the first material film MF1 and the third material film MF3 is completed.

Next, the manufacturing apparatus fills the trench 21 with the isolation film 22. Next, the manufacturing apparatus performs CMP processing on the surface of the isolation film 22 to remove the isolation film 22 from regions other than the trench 21 on the side of the rear surface 10b of the semiconductor substrate 10. The photodetector 1 shown in FIG. 1 is completed through the above processes.

### (Advantageous Effects of Embodiment)

As described above, the photodetector 1 according to an embodiment of the present disclosure includes the semiconductor substrate 10 having the front surface 10a and the rear surface 10b located on the opposite side to the front surface 10a, the plurality of pixels 12 provided on the semiconductor substrate 10 and having the photodiodes PD, the inter-pixel isolation part 20 provided between one and the other of adjacent pixels 12 among the plurality of pixels 12 and penetrating between the front surface 10a and the rear surface 10b of the semiconductor substrate 10, and the surrounding part 30 provided on the side of the front surface 10a of the semiconductor substrate 10 and surrounding an end 20a of the inter-pixel isolation part 20, wherein the surrounding part 30 is made of a material different from that of the semiconductor substrate 10.

For example, the semiconductor substrate 10 is made of single crystal silicon (Si). The surrounding part 30 is made of silicon nitride (SiN), or silicon nitride containing at least one of oxygen and carbon (SiON, SiCN). In addition, the mask M3 used at the time of forming the trench 21 of the inter-pixel isolation part 20 is made of silicon oxide (SiO).

According to this, on the side of the front surface 10a of the semiconductor substrate 10, the surrounding part 30 is interposed between the opening end of the trench 21 of the inter-pixel isolation part 20 and the insulating films 41, 42, 43, and 44 covering the front surface 10a. When the mask M3 is removed by wet etching, even if a chemical solution (for example, a solution containing hydrofluoric acid (HF)) enters from the side of the rear surface 10b of the semiconductor substrate 10 to the side of the front surface 10a of the semiconductor substrate 10 through the trench 21, the surrounding part 30 can prevent the chemical solution from contacting the insulating films 41, 42, 43, and 44.

Accordingly, the chemical solution for removing the mask M3 can be prevented from infiltrating along the front surface 10a of the semiconductor substrate 10 from the opening end of the trench 21. The insulating films 41, 42, 43, and 44 covering the front surface 10a of the semiconductor substrate 10 and the via 50 connected to the front surface 10a of the semiconductor substrate 10 can be prevented from being eroded by the chemical solution for removing the mask M3, and the occurrence of contact failure of the via 50 due to infiltration of the chemical solution and erosion can be suppressed. This makes it possible to suppress a decrease in the yield of the photodetector 1.

The method of manufacturing the photodetector 1 according to an embodiment of the present disclosure includes a process of forming the first material film MF1 on the side of the front surface 10a of the semiconductor substrate 10 having the front surface 10a and the rear surface 10b located on the opposite side to the front surface 10a, and having the plurality of pixels 12 each having the photodiode PD provided thereon, and covering the predetermined region 20′ for isolating adjacent pixels 12 from each other among the plurality of pixels 12 with the first material film MF1 on the side of the front surface 10a, a process of forming the second material film MF2 on the opposite side of the predetermined region 20′ with the first material film MF1 interposed therebetween, a process of forming the third material film MF3 on the opposite side of the first material film MF1 with the second material film MF2 interposed therebetween and surrounding the second material film MF2 with the first material film MF1 and the third material film MF3, a process of forming the mask M3 having a shape that exposes the predetermined region 20′ and covers the region other than the predetermined region 20′ on the rear surface 10b, a process of forming the trench 21 penetrating the semiconductor substrate 10 and the first material film MF1 by etching the predetermined region 20′ exposed through the mask M3 on the side of the rear surface 10b using the second material film MF2 as an etching stopper, and a process of removing the mask M3 by wet etching after forming the trench 21. In this wet etching, a chemical solution by which the mask M3 and the second material film MF2 are easily etched, and the first material film MF1 and the third material film MF3 are hardly etched is used.

For example, the mask M3 and the second material film MF2 are made of silicon oxide. The first material film MF1 and the third material film MF3 are made of silicon nitride (SiN) or silicon nitride containing at least one of oxygen and carbon (SiON, SiCN). The chemical solution for removing the mask M3 contains hydrofluoric acid (HF).

According to this, even if the chemical solution for removing the mask M3 enters from the side of the rear surface 10b of the semiconductor substrate 10 through the trench 21 to the side of the front surface 10a in the process of removing the mask M3, the surrounding part 30 can prevent the chemical solution from contacting the insulating films 41, 42, 43, and 44 covering the side of the front surface 10a of the semiconductor substrate 10. Accordingly, the chemical solution for removing the mask M3 can be prevented from infiltrating along the front surface 10a of the semiconductor substrate 10 from the opening end of the trench 21.

In the process of removing the mask M3, the insulating films 41, 42, 43, and 44 covering the side of the front surface 10a of the semiconductor substrate 10 and the via 50 connected to the front surface 10a of the semiconductor substrate 10 can be prevented from being eroded by the chemical solution for removing the mask M3, and the occurrence of contact failure of the via 50 due to infiltration of the chemical solution or erosion can be suppressed. This makes it possible to suppress a decrease in the yield of the photodetector 1.

As a comparative example of the present disclosure, a method of filling a photoresist in the trench without providing the surrounding part in advance at the time of removing the mask may be considered. In the method of this comparative example, the resist is liable to be cracked, and there is a possibility of the chemical solution infiltrating into the front surface side of the semiconductor substrate through cracks. In this case, since there is no surrounding part below the trench, there is a possibility of occurrence of a contact failure due to erosion. On the other hand, in the embodiment of the present disclosure, the above-described surrounding part 30 is provided below the trench, and thus the occurrence of a contact failure due to erosion can be suppressed. Further, in the embodiment of the present disclosure, it is not necessary to fill a resist in the trench 21 when removing the mask M3.

### MODIFIED EXAMPLES

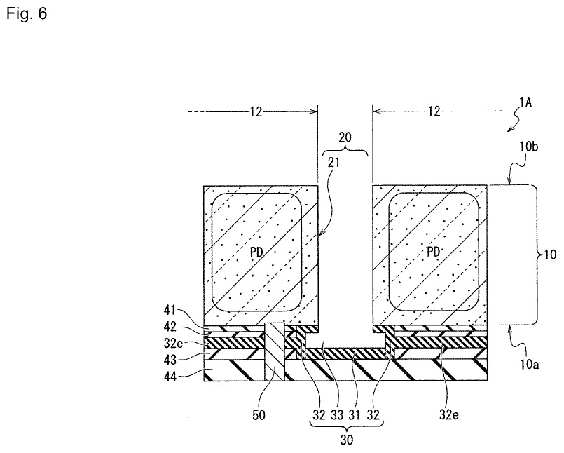

A plurality of modified examples of the embodiment of the present disclosure will be described below. In FIG. 6 to FIG. 15 showing the modified examples, the isolation film 22 (refer to FIG. 1) is omitted in order to make the shape of the surrounding part 30 easy to see.

### (1) Modified Example 1

FIG. 6 is a cross-sectional view showing a photodetector 1A according to modified example 1 of the embodiment of the present disclosure. The photodetector 1A shown in FIG. 6 differs from the photodetector 1 shown in FIG. 1 in that the step portion G32 (refer to FIG. 1) is not provided on the inner surface of the side portion 32 of the surrounding part 30. Such a structure can be realized by, for example, forming the mask M2 with a narrow width such that the mask M2 does not cover the edge of the opening H11 in step ST6 of FIG. 3.

In the photodetector 1A having such an aspect, the insulating films 41, 42, 43, and 44 covering the side of the front surface 10a of the semiconductor substrate 10 and the via 50 connected to the front surface 10a of the semiconductor substrate 10 can be prevented from being eroded by the chemical solution for removing the mask, and thus a decrease in yield can be suppressed as in the photodetector 1.

### (2) Modified Example 2

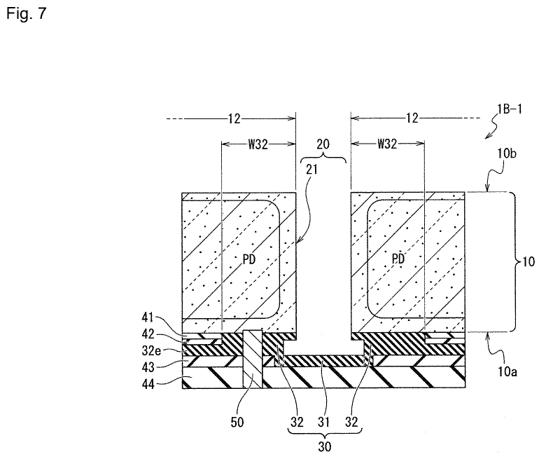

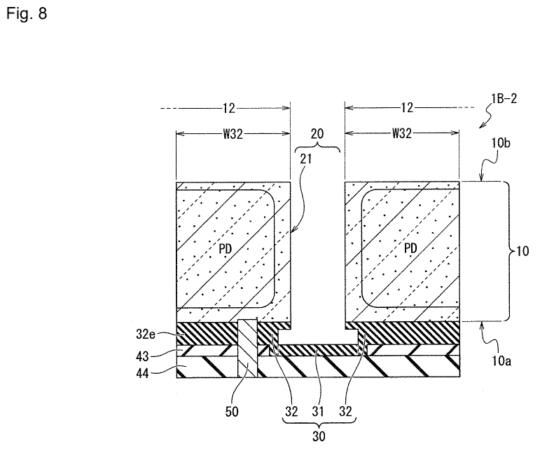

FIG. 7 is a cross-sectional view showing a photodetector 1B-1 according to modified example 2-1 of the embodiment of the present disclosure. FIG. 8 is a cross-sectional view showing a photodetector 1B-2 according to modified example 2-2 of the embodiment of the present disclosure. The photodetectors 1B-1 and 1B-2 shown in FIG. 7 and FIG. 8 differ from the photodetectors 1 and 1A in that the line width W32 of the portion of the side portion 32 that contacts the front surface 10a of the semiconductor substrate 10 is expanded toward the outside of the inter-pixel isolation part 20 (i.e., toward the side of the pixel 12). The photodetector 1B-2 is an example in which the line width W32 is further expanded compared with the photodetector 1B-1, and for example, the side portion 32 is extended over the entire surface of the pixels 12 except for the region in contact with the via 50 or a region in which the gate electrode of the pixel transistor (not shown) is disposed.

Such a structure can be realized by, for example, forming the opening H11 wider than the predetermined region 20′ where the inter-pixel isolation part 20 will be formed in step ST4 of FIG. 3.

In the photodetectors 1B-1 and 1B-2 having such an aspect, the insulating films covering the side of the front surface 10a of the semiconductor substrate 10 and the via 50 connected to the front surface 10a of the semiconductor substrate 10 can be prevented from being eroded by the chemical solution for removing the mask, as in the photodetectors 1 and 1A, and thus a decrease in yield can be suppressed.

Further, since a horizontal distance from the trench 21 of the inter-pixel isolation part 20 to the insulating films can be increased in the photodetectors 1B-1 and 1B-2, the chemical solution can be further prevented from infiltrating in the horizontal direction from the trench 21, for example, at the time of removing the hard mask HM shown in steps ST11 and ST12 of FIG. 5. Accordingly, for example, a contact failure of the via 50 due to infiltration of the chemical solution or erosion can be further suppressed, and a margin of the contact failure can be further expanded.

### (3) Modified Example 3

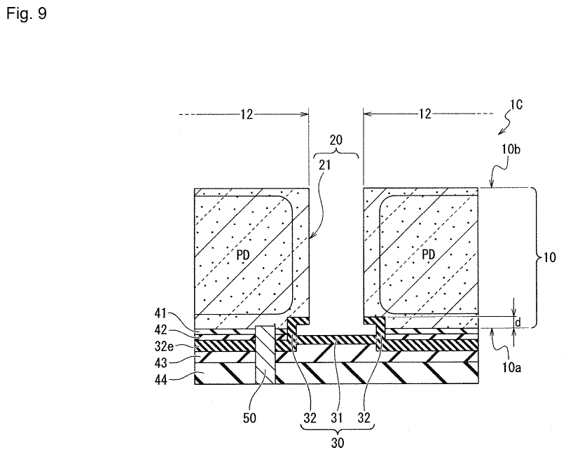

FIG. 9 is a cross-sectional view showing a configuration example of a photodetector 1C according to modified example 3 of the embodiment of the present disclosure. The photodetector 1C shown in FIG. 9 differs from the above-described photodetectors 1 and 1A in that the surrounding part 30 is formed to be embedded into the semiconductor substrate 10. For example, the edge of the trench 21 is engraved by a depth d from the front surface 10a of the semiconductor substrate 10. The side portion 32 of the surrounding part 30 is provided at the engraved edge of the trench 21.

Such a structure can be realized by, for example, etching and engraving the semiconductor substrate 10 from the side of the front surface 10a using the insulating film 42 as a mask in step ST3 of FIG. 2, and forming the first material film MF1 on the side of the front surface 10a of the engraved semiconductor substrate 10.

In the photodetector 1C having such an aspect, the insulating films covering the side of the front surface 10a of the semiconductor substrate 10 and the via 50 connected to the front surface 10a of the semiconductor substrate 10 can be prevented from being eroded by the chemical solution for removing the mask, and thus a decrease in yield can be suppressed as in the photodetectors 1 and 1A.

Further, in the process of manufacturing the photodetector 1C, since the side of the front surface 10a of the semiconductor substrate 10 is engraved in advance, the etching depth of the trench 21 formed on the side of the rear surface 10b can be reduced in step ST11 of FIG. 5. This facilitates the formation of the trench 21 even when the thickness of the semiconductor substrate 10 is increased.

### (4) Modified Example 4

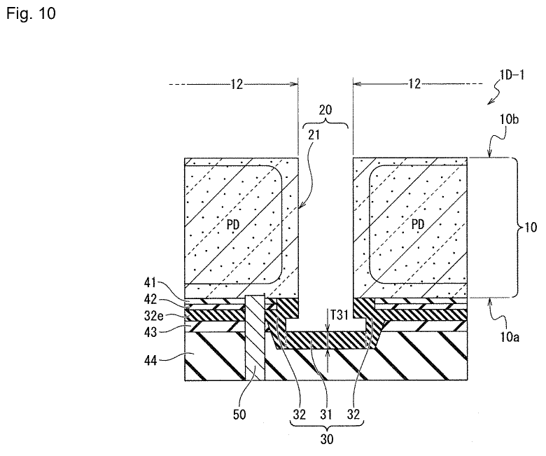

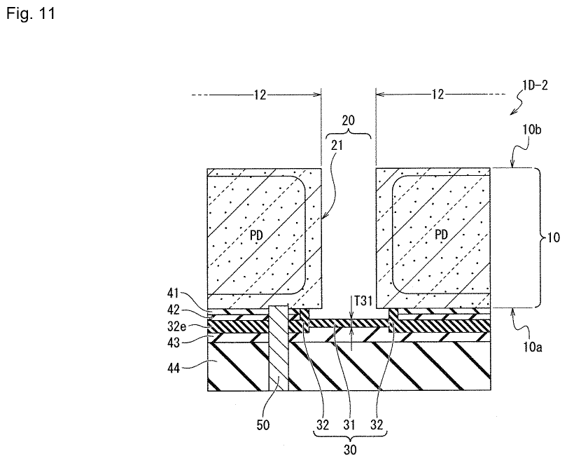

FIG. 10 is a cross-sectional view showing a photodetector 1D-1 according to modified example 4-1 of the embodiment of the present disclosure. FIG. 11 is a cross-sectional view showing a photodetector 1D-2 according to modified example 4-2 of the embodiment of the present disclosure. The photodetectors 1D-1 and 1D-2 shown in FIG. 10 and FIG. 11 differ from the above-described photodetectors 1 and 1A with respect to the thickness T31 of the bottom portion 31 of the surrounding part 30. The photodetector 1D-1 is an example in which the thickness T31 of the bottom portion 31 is increased (i.e., the bottom portion 31 has an increased thickness). The photodetector 1D-2 is an example in which the thickness T31 of the bottom portion 31 is reduced (i.e., the bottom portion 31 has a reduced thickness).

As shown in the photodetectors 1D-1 and 1D-2, the bottom portion 31 of the surrounding part 30 may be made thick or thin. The thickness of the bottom portion 31 is adjusted by, for example, the thickness of the third material film MF3 formed in step ST8 of FIG. 4.

In the photodetectors 1D-1 and 1D-2 having such an aspect, the insulating films covering the side of the front surface 10a of the semiconductor substrate 10 and the via 50 connected to the front surface 10a of the semiconductor substrate 10 can be prevented from being eroded by the chemical solution for removing the mask, as in the photodetectors 1 and 1A, and thus a decrease in yield can be suppressed.

Further, since the bottom portion 31 may be made thick or thin, for example, the film thickness margin of the third material film MF3 can be increased.

### (5) Modified Example 5

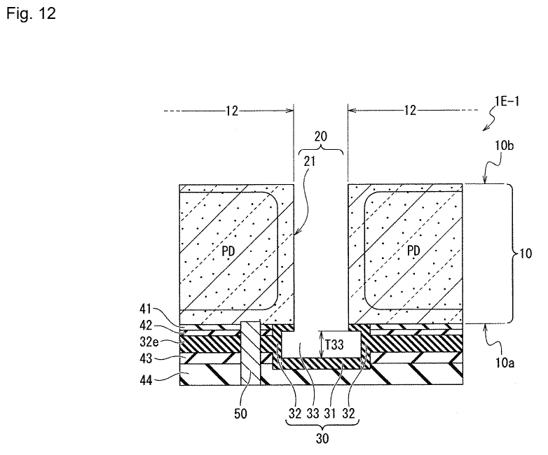

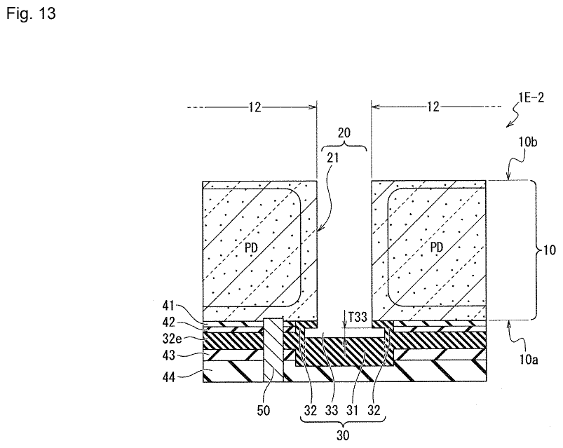

FIG. 12 is a cross-sectional view showing a photodetector 1E-1 according to modified example 5-1 of the embodiment of the present disclosure. FIG. 13 is a cross-sectional view showing a photodetector 1E-2 according to modified example 5-2 of the embodiment of the present disclosure. The photodetectors 1E-1 and 1E-2 shown in FIG. 12 and FIG. 13 differ from the above-described photodetectors 1 and 1A with respect to the thickness T33 of the space 33 inside the surrounding part 30. The photodetector 1E-1 is an example in which the depth T33 of the space 33 is increased. The photodetector 1E-2 is an example in which the depth T33 of the space 33 is reduced.

As shown in the photodetectors 1E-1 and 1E-2, the space 33 of the surrounding part 30 may be deep or shallow. The depth of the space 33 is adjusted by, for example, the thickness of the second material film MF2 formed in step ST5 of FIG. 3.

In the photodetectors 1E-1 and 1E-2 having such an aspect, the insulating films covering the side of the front surface 10a of the semiconductor substrate 10 and the via 50 connected to the front surface 10a of the semiconductor substrate 10 can be prevented from being eroded by the chemical solution for removing the mask, as in the photodetectors 1 and 1A, and thus a decrease in yield can be suppressed.

Further, since the space 33 may be made deep or shallow, the film thickness margin of the second material film MF2 can be increased.

### (6) Modified Example 6

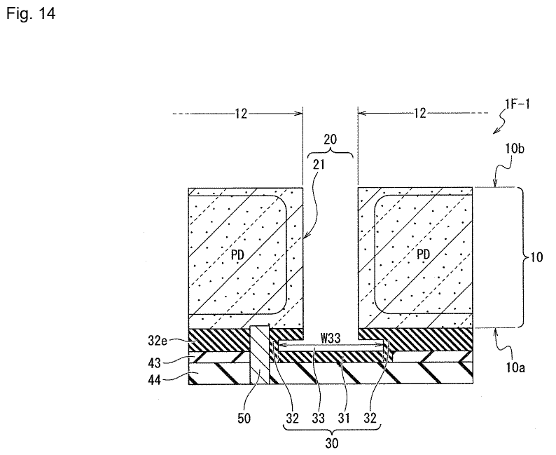

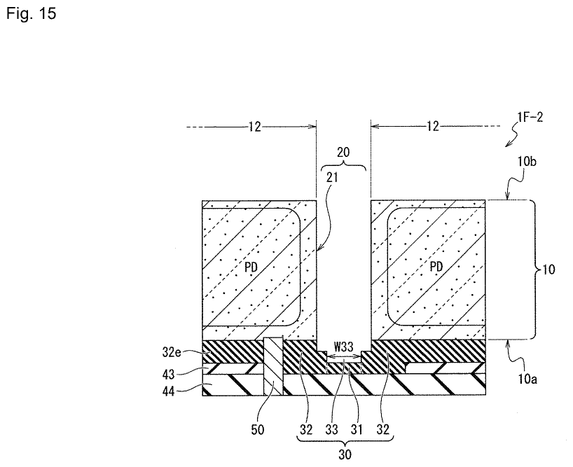

FIG. 14 is a cross-sectional view showing a photodetector 1F-1 according to modified example 6-1 of the embodiment of the present disclosure. FIG. 15 is a cross-sectional view showing a photodetector 1F-2 according to modified example 6-2 of the embodiment of the present disclosure. The photodetectors 1F-1 and 1F-2 shown in FIG. 14 and FIG. 15 differ from the above-described photodetectors 1 and 1A with respect to the width of the space 33 inside the surrounding part 30. The photodetector 1F-1 is an example in which the width of the space 33 is increased. The photodetector 1F-2 is an example in which the width of the space 33 is reduced.

As shown in the photodetectors 1F-1 and 1F-2, in the space 33 of the surrounding part 30, the width W33 of a region close to the bottom portion 31 may be increased or reduced. The width W33 of the region close to the bottom portion 31 is adjusted by, for example, the line width of the mask M2 formed in step ST6 of FIG. 3 (i.e., the line width of the second material film MF2 shown in step ST7 of FIG. 4).

In the photodetectors 1F-1 and 1F-2 having such an aspect, the insulating films covering the side of the front surface 10a of the semiconductor substrate 10 and the via 50 connected to the front surface 10a of the semiconductor substrate 10 can be prevented from being eroded by the chemical solution for removing the mask, as in the photodetectors 1 and 1A, and thus a decrease in yield can be suppressed. Further, since the line width of the second material film MF2 may be increased or reduced, the line width margin of the second material film MF2 can be increased.

### APPLICATION EXAMPLES

The technique of the present disclosure can be applied to various photodetectors such as indirect ToF (Time of Flight) type ranging sensors, direct ToF type ranging sensors, and CMOS image sensors. A plurality of examples to which the technique of the present disclosure is applied are shown below.

### (1) Application Example 1; Application to Indirect ToF Type Ranging Sensor

Application example 1 is an example in which the technique of the present disclosure is applied to an imaging element (light-receiving element) constituting a ranging sensor that performs distance measurement using an indirect ToF method, and an imaging device including such an imaging element, and the like. For example, the ranging sensor can be applied to an in-vehicle system that is mounted in a vehicle and measures a distance to an object outside of the vehicle, a gesture recognition system that measures a distance to an object such as a hand of a user and recognizes a gesture of the user on the basis of a measurement result, and the like. In this case, a result of gesture recognition can be used for, for example, an operation or the like of a car navigation system.

### <1-1) Application Example 1-1

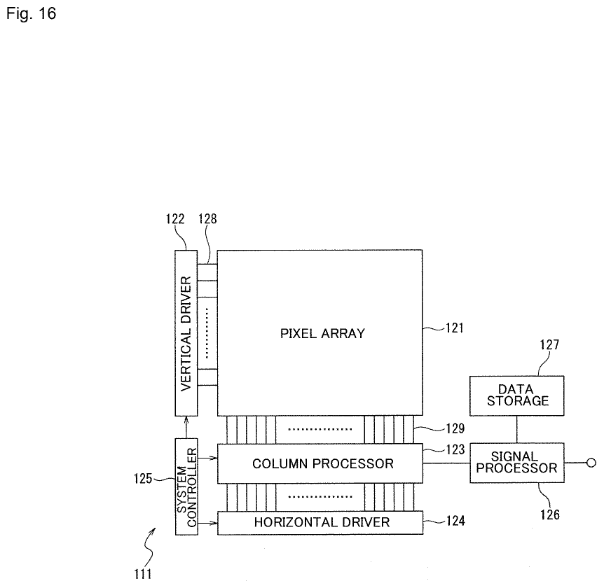

FIG. 16 is a diagram showing a configuration of an imaging element according to application example 1-1 of the present disclosure. The imaging element 111 shown in FIG. 16 is a backside illumination type current assisted photonic demodulator (CAPD) sensor, which is provided in an imaging device having a distance measurement function. CAPD is an indirect ToF type ranging sensor that applies a voltage directly to a sensor substrate to generate a current within the substrate, for example, such that a wide area within the substrate can be rapidly modulated.

The imaging element 111 includes a pixel array 121 formed on a semiconductor substrate, which is not illustrated, and peripheral circuits integrated on the same semiconductor substrate as the pixel array 121. The peripheral circuits include, for example, a vertical driver 122, a column processor 123, a horizontal driver 124, and a system controller 125.

The imaging element 111 is further provided with a signal processor 126 and a data storage 127. The signal processor 126 and the data storage 127 may be mounted on the same substrate as the imaging element 111 or may be disposed on a different substrate from the imaging element 111 in the imaging device.

The pixel array 121 has a configuration in which unit pixels (hereinafter, simply referred to as pixels) that generate charges corresponding to the amount of received light and output a signal corresponding to the charges are disposed in a row direction and a column direction, that is, disposed two-dimensionally in a matrix form. That is, the pixel array 121 includes a plurality of pixels that perform photoelectric conversion of incident light and output a signal in accordance with charges obtained as a result of the photoelectric conversion.

Here, the row direction is a direction in which pixels in a pixel row are disposed (that is, a horizontal direction), and the column direction is a direction in which pixels in a pixel column are disposed (that is, a vertical direction). That is, the row direction is a transverse direction in the figure, and the column direction is a longitudinal direction in the figure.

In the pixel array 121, a pixel driving line 128 is wired in the row direction for each pixel row and two vertical signal lines 129 are wired in the column direction for each pixel column in the pixel array in a matrix form. For example, the pixel driving line 128 transfers a driving signal for driving at the time of reading a signal from a pixel. Note that although one wire is shown as the pixel driving line 128 in FIG. 16, the present disclosure is not limited to one line. One end of the pixel driving line 128 is connected to an output terminal of the vertical driver 122 corresponding to each row.

The vertical driver 122 is composed of a shift register, an address decoder, and the like, and drives all of the pixels of the pixel array 121 at the same time, in units of rows, or the like. That is, the vertical driver 122 constitutes a driver that controls the operation of each pixel of the pixel array 121 along with the system controller 125 that controls the vertical driver 122.

In indirect ToF type distance measurement, the number of elements (CAPD elements) that are connected to one control line and perform high-speed driving affects controllability of high-speed driving and the accuracy of driving. Many solid-state image sensors used for the indirect ToF type distance measurement have a pixel array that is long in the horizontal direction. Accordingly, in this case, the vertical signal lines 129 or other vertically long control lines may be used as control lines for an element that performs high-speed driving. In this case, for example, a plurality of pixels arranged in the vertical direction are connected to vertical signal lines 129 or other vertically long control lines, and the pixels are driven, i.e., the CAPD sensor is driven, by a driver provided separately from the vertical driver 122 or the horizontal driver 124 via the vertical signal lines 129 or other control lines.

A signal output from each pixel in a pixel row in response to driving control by the vertical driver 122 is input to the column processor 123 through the vertical signal line 129. The column processor 123 performs predetermined signal processing on the signal output from each pixel through the vertical signal line 129, and temporarily holds the pixel signal after the signal processing. Specifically, the column processor 123 performs noise removal processing, analog-to-digital (AD) conversion processing, and the like as the signal processing.

The horizontal driver 124 is composed of a shift register, an address decoder, and the like, and sequentially selects unit circuits corresponding to a pixel column in the column processor 123. Pixel signals subjected to signal processing for each unit circuit in the column processor 123 are sequentially output according to selective scanning of the horizontal driver 124.

The system controller 125 is composed of a timing generator that generates various timing signals, and the like, and controls driving of the vertical driver 122, the column processor 123, the horizontal driver 124, and the like on the basis of various timings generated by the timing generator.

The signal processor 126 has at least an arithmetic operation processing function, and performs various kinds of signal processing such as arithmetic operation processing on the basis of pixel signals output from the column processor 123. The data storage 127 temporarily stores data required for signal processing in the signal processor 126 at time of performing the signal processing.

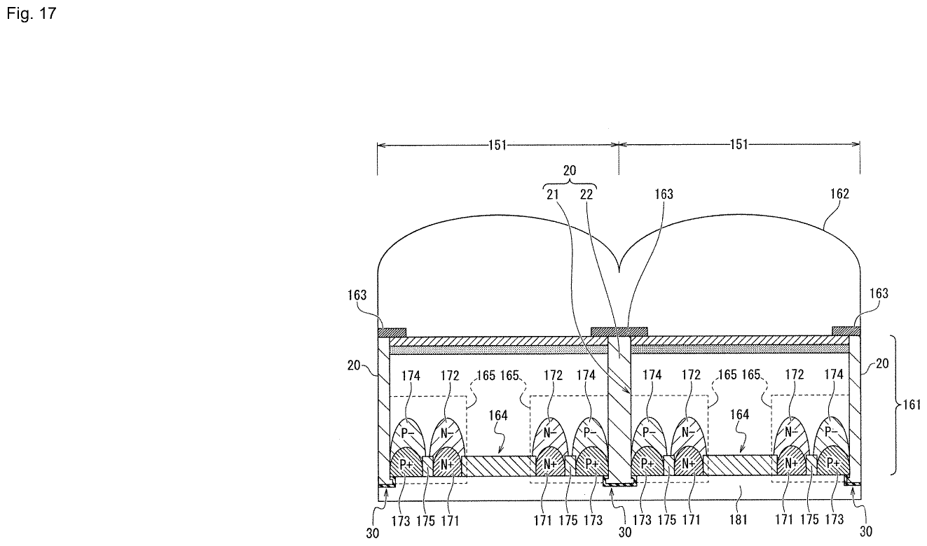

Next, a configuration example of a pixel provided in the pixel array 121 will be described. A pixel provided in the pixel array 121 is configured as shown in FIG. 17, for example.

FIG. 17 is a cross-sectional view showing a configuration of a pixel array 121 according to application example 1-1 of the present disclosure. FIG. 17 shows the cross-section of one pixel 151 provided in the pixel array 121, and this pixel 151 receives and photoelectrically converts light incident from the outside, particularly infrared light, and outputs a signal corresponding to the resulting charges. The pixel 151 includes, for example, a silicon substrate, that is, a substrate 161 (an example of a “semiconductor substrate” in the present disclosure) which is a P-type semiconductor substrate composed of a P-type semiconductor region, and an on-chip lens 162 formed on the substrate 161.

In the figure, on the upper surface of the substrate 161, that is, on the surface of the substrate 161 on which light from the outside is incident (an example of a “second surface” in the present disclosure; also referred to as an incident surface hereinafter), the on-chip lens 162 which collects light incident from the outside and causes the same to enter the substrate 161 is formed. Further, in the pixel 151, an inter-pixel light-shielding part 163 is formed at an end of the pixel 151 on the light incident surface of the substrate 161 to prevent color mixture between adjacent pixels.

In this example, light from the outside is incident on the inside of the substrate 161 through the on chip lens 162, but the light incident from the outside passes through the on-chip lens 162 and a part of the substrate 161 and is prevented from being incident on the regions of other pixels provided adjacent to the pixel 151 on the substrate 161. That is, light incident on the on-chip lens 162 from the outside and being directed into other pixels adjacent to the pixel 151 is blocked by the inter-pixel light shielding part 163 and thus is not incident on the other adjacent pixels.

Since the imaging element 111 is a backside illumination type CAPD sensor, the light incident surface of the substrate 161 is a so-called rear surface, and a wiring layer made of wiring lines or the like is not formed on the rear surface. Further, on the surface of the substrate 161 opposite the incident surface, wiring layers in which a wiring line for driving transistors and the like formed in the pixel 151, a wiring line for reading out signals from the pixel 151, and the like are formed in a laminated manner.

An oxide film 164 and a signal extraction part 165 called a tap are formed on the side of the surface (an example of a “first surface” in the present disclosure) opposite the incident surface in the substrate 161, that is, on the inner side of the lower surface in the figure.

In this example, the oxide film 164 is formed in the center portion of the pixel 151 in the vicinity of the surface of the substrate 161 opposite to the light incident surface, and the signal extraction part 165 is formed on both ends of the oxide film 164.

Here, the signal extraction part 165 has an N− semiconductor region 172 having a lower concentration of donor impurities than an N+ semiconductor region 171 which is an N-type semiconductor region, a P+ semiconductor region 173 which is a P-type semiconductor region, and a P− semiconductor region 174 having a lower concentration of acceptor impurities than the P+ semiconductor region 173. Here, the donor impurities include elements belonging to Group 5 of the periodic table of elements, such as phosphorus (P) and arsenic (As) for Si, for example. The acceptor impurities include elements belonging to Group 3 of the periodic table of elements, such as boron (B) for Si, for example. An element serving as donor impurities will be referred to as a donor element and an element serving as acceptor impurities will be referred to as an acceptor element.

In addition, an isolation part 175 for isolating the N+ semiconductor region 171 and the P+ semiconductor region 173 from each other is formed of an oxide film or the like between the regions in the substrate 161.

The N+ semiconductor region 171 provided in the substrate 161 functions as a charge detection portion for detecting the amount of light that is incident on the pixel 151 from the outside, that is, the amount of signal carriers generated through photoelectric conversion in the substrate 161. The electric charge detecting portion can also be regarded as including the N− semiconductor region 172 with a low concentration of donor impurities in addition to the N+ semiconductor region 171. In addition, the P+ semiconductor region 173 functions as a voltage applying portion for injecting a majority carrier current into the substrate 161, that is, directly applying a voltage to the substrate 161 to generate an electric field inside the substrate 161. Note that it is also possible to regard the P− semiconductor region 174 having low acceptor impurity concentration as a voltage application portion in addition to the P+ semiconductor region 173.

In each of the plurality of pixels 151 shown in FIG. 17, a floating diffusion (FD) portion (hereinafter also referred to as FD portion A) which is a floating diffusion region that is not shown is directly connected to one of two N+ semiconductor regions 171, and the FD portion A is connected to the vertical signal line 129 via an amplification transistor that is not shown.

Similarly, another FD portion (hereinafter also referred to as an FD portion B) different from the FD portion A is directly connected to the other N+ semiconductor region 171 of the two N+ semiconductor regions 171, and the FD portion B is connected to the vertical signal line 129 via an amplification transistor that is not shown. The FD portion A and the FD portion B are connected to different vertical signal lines 129.

For example, when the distance to an object is to be measured by the indirect ToF method, infrared light is emitted from the imaging device provided with the imaging element 111 toward the object. Then, when the infrared light is reflected by the object and returns to the imaging device as reflected light, the substrate 161 of the imaging element 111 receives and photoelectrically converts the incident reflected light (infrared light). At this time, the vertical driver 122 drives the pixel 151 and distributes signals in accordance with charges obtained due to photoelectric conversion to the FD portion A and the FD portion B. As described above, the pixel 151 may be driven not by the vertical driver 122 but by a separately provided driver or the horizontal driver 124 via the vertical signal lines 129 or other vertically long control lines.

For example, at a certain timing, the vertical driver 122 applies a voltage to the two P+ semiconductor regions 173 via contacts or the like. Specifically, for example, the vertical driver 122 applies a voltage of 1.5 V to one of the two P+ semiconductor regions 173 disposed in the pixel 151 and applies a voltage of 0 V to the other P+ semiconductor region 173. Then, an electric field is generated between the two P+ semiconductor regions 173 on the substrate 161, and a current flows from one P+ semiconductor region 173 to the other P+ semiconductor region 173. In this case, holes in the substrate 161 move toward the other P+ semiconductor region 173, and electrons move toward the one P+ semiconductor region 173.

Therefore, when infrared light (reflected light) from the outside is incident on the inside of the substrate 161 via the on-chip lens 162 in this state and the infrared light is photoelectrically converted in the substrate 161 into pairs of electrons and holes, the obtained electrons are guided in the direction of one P+ semiconductor region 173 by the electric field between the P+ semiconductor regions 173 and move into one N+ semiconductor region 171 adjacent to the one P+ semiconductor region 173 via the isolation part 175.

In this case, the electrons generated by photoelectric conversion are used as signal carriers for detecting a signal in accordance with the amount of infrared light incident on the pixel 151, that is, the amount of received infrared light. Accordingly, charges in accordance with the electrons that have moved into the one N+ semiconductor region 171 are accumulated in the one N+ semiconductor region 171, and these charges are detected by the column processor 123 via the FD portion A, the amplification transistor, the vertical signal line 129, and the like.

That is, the charge accumulated in the one N+ semiconductor region 171 is transferred to the FD portion A that is directly connected to the one N+semiconductor region 171, and a signal in accordance with the charges transferred to the FD portion A is read by the column processor 123 via the amplification transistor and the vertical signal line 129. Then, processing such as AD conversion is performed on the read signal by the column processor 123 and a pixel signal obtained as a result of the processing is supplied to the signal processor 126.

This pixel signal is a signal indicating the amount of charges in accordance with the electrons detected by the one N+ semiconductor region 171, that is, the amount of charges accumulated in the FD portion A. In other words, the pixel signal can be a signal indicating the amount of infrared light received by the pixel 151.

In this case, a pixel signal in accordance with electrons detected by the other N+ semiconductor region 171 adjacent to the other P+ semiconductor region 173 via the isolation part 175 may be used for distance measurement appropriately similarly to the case of the one N+ semiconductor region 171.

Further, at a next timing, a voltage is applied to the two P+ semiconductor regions 173 via contacts by the vertical driver 122 such that an electric field is generated in the opposite direction to the electric field that has been generated in the substrate 161 up until now. Specifically, for example, a voltage of 1.5 V is applied to the other P+ semiconductor region 173 of the two P+ semiconductor regions 173 disposed in the pixel 151 and a voltage of 0 V is applied to the one P+ semiconductor region 173.

As a result, an electric field is generated between the two P+ semiconductor regions 173 in the substrate 161, and a current flows from the other P+ semiconductor region 173 to one P+ semiconductor region 173. In this state, when infrared light (reflected light) from the outside is incident on the substrate 161 through the on-chip lens 162 and the infrared light is photoelectrically converted into electron-hole pairs within the substrate 161, the obtained electrons are guided in the direction of the other P+ semiconductor region 173 by the electric field between the P+semiconductor regions 173, and move into the other N+ semiconductor region 171. Accordingly, charges in accordance with the electrons that have moved into the other N+ semiconductor region 171 are accumulated in the other N+ semiconductor region 171, and these charges are detected by the column processor 123 via the FD portion B, the amplification transistor, the vertical signal line 129, and the like.

That is, the charges accumulated in the other N+ semiconductor region 171 are transferred to the FD portion B that is directly connected to the other N+semiconductor region 171, and a signal in accordance with the charges transferred to the FD portion B is read by the column processor 123 via the amplification transistor and the vertical signal line 129. In addition, processing such as AD conversion is performed on the read signal by the column processor 123 and a pixel signal obtained as a result of the processing is supplied to the signal processor 126.

In this case, a pixel signal in accordance with electrons detected by one N+ semiconductor region 171 may be used for distance measurement appropriately similarly to the case of the other N+ semiconductor region 171.

In this manner, when pixel signals are obtained by photoelectric conversions performed during different periods in the same pixel 151, the signal processor 126 calculates distance information indicating a distance to the object on the basis of the pixel signals and outputs the distance information to the next stage. This method of distributing signal carriers to different N+ semiconductor regions 171 and calculating distance information on the basis of signals corresponding to those signal carriers is called an indirect ToF method.

Although an example in which the vertical driver 122 controls application of voltages to the P+ semiconductor regions 173 has been described here, the imaging element 111 may be provided with a driver (block) that functions as a voltage application controller for controlling application of voltages to the P+ semiconductor regions 173, separately from the vertical driver 122, as described above.

Further, in this example, an embedded isolation region is formed in the pixel 151. For example, as shown in FIG. 17, the inter-pixel isolation part 20 penetrating the entire substrate 161 is provided. In the pixel 151 shown in FIG. 17, the inter-pixel isolation part 20 penetrating the entire substrate 161 is formed at a boundary portion between the pixel 151 and another pixel 151 adjacent to the pixel 151 in the substrate 161.

For example, when the inter-pixel isolation part 20 is formed, the trench 21 is formed from the surface on the side of the light incident surface of the substrate 161, that is, the upper surface in the figure. At this time, the trench is formed to penetrate the substrate 161. Then, the isolation film 22 such as a light-shielding film is formed in the trench portion formed in such a manner by embedding to form an inter-pixel isolation part 20. Such an embedded inter-pixel isolation part 20 can improve the isolation characteristics of infrared light between pixels, and can suppress the occurrence of color mixture.

Further, the surrounding part 30 which surrounds an end of the inter-pixel isolation part 20 is provided on the surface opposite to the light incident surface of the substrate 161, that is, on the lower surface side in the figure. The surrounding part 30 is covered from the bottom with an interlayer insulating film 181 or the like of the multilayered wiring layer disposed on the bottom surface in the figure. As in the above embodiment, in this application example 1-1, the surrounding part 30 is made of a material different from that of the substrate 161, and is made of, for example, silicon nitride (SiN), or silicon nitride containing at least one of oxygen and carbon (SiON, SiCN).

In the above-described application example 1-1, the surrounding part 30 is also formed in advance when the trench 21 is formed. Accordingly, as in the above embodiment, when the hard mask (for example, SiO) used at the time of forming the trench 21 is removed, it is possible to prevent the insulating film (e.g., interlayer insulating film 181) covering the opposite side to the light incident surface of the substrate 161 and the via connected to the opposite side to the light incident surface of the substrate 161 from being eroded by the chemical solution for removing the hard mask, and thus a decrease in yield can be suppressed.

### (1-2) Application Example 1-2

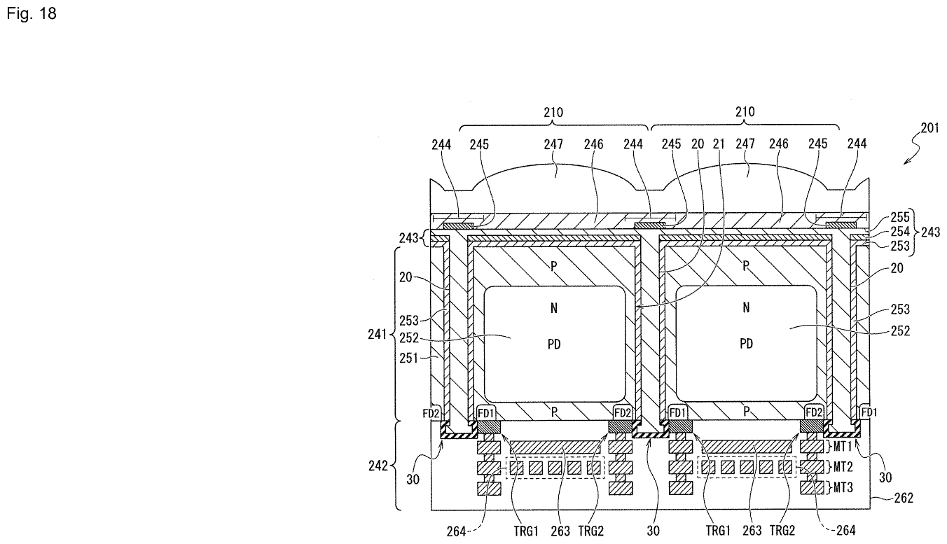

FIG. 18 is a cross-sectional view showing a configuration of a pixel array of a light-receiving element 201 according to application example 1-2 of the present disclosure. The light-receiving element 201 includes a semiconductor substrate 241 and a multilayered wiring layer 242 formed on the side (the lower side in the figure) of the front surface (an example of the “first surface” in the present disclosure) of the semiconductor substrate 241.

The semiconductor substrate 241 is made of silicon (Si), for example, and is formed to have a thickness of 1 to 6 μm, for example. In the semiconductor substrate 241, for example, an N-type (second conductivity type) semiconductor region 252 is formed in a P-type (first conductivity type) semiconductor region 251 for each pixel, thereby forming a photodiode PD for each pixel. The P-type semiconductor regions 251 provided on both the front and rear surfaces of the semiconductor substrate 241 also serve as hole charge accumulation regions for inhibiting a dark current.

The upper surface of the semiconductor substrate 241 which is located on the upper side in FIG. 18 is the rear surface of the semiconductor substrate 241 and is a light incident surface on which light is incident. An anti-reflection film 243 is formed on the upper surface of the semiconductor substrate 241 on the rear surface side.

The anti-reflection film 243 has, for example, a laminated structure in which a fixed charge film and an oxide film are laminated, and a high-dielectric constant (high-k) thin insulating film formed according to an atomic layer deposition (ALD) method can be used as the anti-reflection film 243. Specifically, hafnium oxide (HfO₂), aluminum oxide (Al₂O₃), titanium oxide (TiO₂), or strontium titan oxide (STO), or the like can be used. In the example in FIG. 18, the anti-reflection film 243 is formed by laminating a hafnium oxide film 253, an aluminum oxide film 254, and a silicon oxide film 255.

An inter-pixel light shielding film 245 that prevents incident light from being incident on adjacent pixels is formed at a boundary portion 244 of adjacent pixels 210 (hereinafter, also referred to as a pixel boundary portion 244) on the semiconductor substrate 241 on the upper surface of the anti-reflection film 243. The material of the inter-pixel light shielding film 245 may be any material as long as it shields light, and a metal material such as tungsten (W), aluminum (Al), or copper (Cu) can be used, for example.

A planarization film 246 is formed of an insulating film such as silicon oxide (SiO), silicon nitride (SiN), or silicon oxynitride (SiON), or an organic material such as a resin, for example, on the upper surface of the anti-reflection film 243 and the upper surface of the inter-pixel light shielding film 245.

In addition, an on-chip lens 247 is formed for each pixel on the upper surface of the planarization film 246. The on-chip lens 247 is formed of, for example, a resin material such as a styrene resin, an acrylic resin, a styrene-acrylic copolymer resin, or a siloxane resin. Light collected by the on-chip lens 247 is efficiently incident on the photodiode PD.

Further, an inter-pixel isolation part 20 that isolates adjacent pixels from each other is formed in the depth direction of the semiconductor substrate 241 to a predetermined depth in the substrate depth direction from the side of the rear surface (the side of the on-chip lens 247) of the semiconductor substrate 241 at the pixel boundary portion 244 on the side of the rear surface of the semiconductor substrate 241.

The inter-pixel isolation part 20 is formed by forming a trench that penetrates from the rear surface side (the side of the on-chip lens 247) of the semiconductor substrate 241 to the front surface of the opposite side, and embedding a silicon oxide film 255 (an example of an “isolation film” in the present disclosure) that is the material of the uppermost layer of the anti-reflection film 243 inside the trench. The material embedded in the trench as the inter-pixel isolation part 20 may be a metal material such as tungsten (W), aluminum (Al), titanium (Ti), or titanium nitride (TiN), for example, in addition to an insulating film such as the silicon oxide film 255.

Adjacent pixels can be completely electrically isolated from each other by forming such an inter-pixel isolation part 20. Accordingly, incident light is prevented from penetrating an adjacent pixel 210 and trapped in the corresponding pixel, and leakage of incident light from an adjacent pixel 210 is prevented.

On the other hand, two transfer transistors TRG1 and TRG2 are formed for one photodiode PD formed for each pixel 210 on the front surface side of the semiconductor substrate 241 on which the multilayered wiring layer 242 is formed. Further, floating diffusion regions FD1 and FD2 as charge accumulation regions that temporarily hold charges transferred from the photodiode PD are formed as high-concentration N-type semiconductor regions (N-type diffusion regions) on the front surface side of the semiconductor substrate 241.

The multilayered wiring layer 242 is composed of a plurality of metal films MT and an interlayer insulating film 262 therebetween. FIG. 18 illustrates an example in which the multilayered wiring layer 242 is composed of three layers, a first metal film MT1 to a third metal film MT3.

A metal wiring layer made of copper, aluminum, or the like is formed as a light shielding member 263 in a region located below a region where the photodiode PD is formed in the first metal film MT1 closest to the semiconductor substrate 241 among the plurality of metal films MT in the multilayered wiring layer 242, in other words, a region that partially overlaps the region where the photodiode PD is formed in a plan view.

The light shielding member 263 shields, with the first metal film MT1 that is the closest to the semiconductor substrate 241, infrared light that is incident on the inside of the semiconductor substrate 241 from the light incident surface via the on-chip lens 247 and has passed through the semiconductor substrate 241 without being photoelectrically converted inside the semiconductor substrate 241 and prevents the infrared light from passing through the second metal film MT2 and the third metal film MT3 below the first metal film MT1. With this light shielding function, it is possible to curb the infrared light that has passed through the semiconductor substrate 241 without being photoelectrically converted inside the semiconductor substrate 241 from being scattering by the metal films MT below the first metal film MT1 and being incident on the surrounding pixels. Accordingly, it is possible to prevent light from being detected erroneously in the surrounding pixels.

Further, the light shielding member 263 also has a function of causing infrared light that is incident on the inside of the semiconductor substrate 241 from the light incident surface via the on-chip lens 247 and has passed through the semiconductor substrate 241 without being photoelectrically converted inside the semiconductor substrate 241 to be reflected by the light shielding member 263 and be incident on the inside of the semiconductor substrate 241 again. Therefore, the light shielding member 263 can also be said to be a reflecting member. This reflecting function can increase the amount of infrared light that is photoelectrically converted inside the semiconductor substrate 241, thereby improving the quantum efficiency (QE), that is, the sensitivity of the pixel 210 to infrared light.

Note that the light shielding member 263 may be formed to have a structure in which reflection or light shielding is achieved using polysilicon, an oxide film, or the like in addition to metal materials.

Further, the light shielding member 263 may be composed of a plurality of metal films MT, for example, the light shielding member 263 may be formed into a grid shape by the first metal film MT1 and the second metal film MT2, instead of the configuration of the single metal film MT.

A wiring capacitor 264 is formed, for example, by patterning a comb-tooth shape in a predetermined metal film MT, for example, the second metal film MT2, among the plurality of metal films MT in the multilayered wiring layer 242. Although the light shielding member 263 and the wiring capacitor 264 may be formed in the same layer (metal film MT), when they are formed in different layers, the wiring capacitor 264 is formed in a layer farther from the semiconductor substrate 241 than the light shielding member 263. In other words, the light shielding member 263 is formed closer to the semiconductor substrate 241 than the wiring capacitor 264.

As described above, the light-receiving element 201 has a backside illumination structure in which the semiconductor substrate 241 that is a semiconductor layer is disposed between the on chip lens 247 and the multilayered wiring layer 242 and incident light is incident on the photodiode PD from the rear surface side where the on-chip lens 247 is formed.

Further, the pixel 210 includes two transfer transistors TRG1 and TRG2 for the photodiode PD provided for each pixel and is configured to be able to distribute charges (electrons) generated through photoelectric conversion by the photodiode PD to the floating diffusion region FD1 or FD2.

Furthermore, the pixel 210 prevents incident light from penetrating into neighboring pixels 210 to trap the incident light in the pixel itself, and prevents the incident light from leaking from adjacent pixels 210 since the inter-pixel isolation part 20 is formed at the pixel boundary portion 244. In addition, infrared light that has passed through the semiconductor substrate 241 without being photoelectrically converted inside the semiconductor substrate 241 is reflected by the light shielding member 263 and is then caused to be incident again on the inside of the semiconductor substrate 241 by providing the light shielding member 263 in the metal film MT below the region where the photodiode PD is formed.

With the above-described configuration, it is possible to increase the amount of infrared light subjected to photoelectric conversion inside the semiconductor substrate 241 and improve quantum efficiency (QE), that is, the sensitivity of the pixel 210 for infrared light.

Further, the surrounding part 30 surrounding an end of the inter-pixel isolation part 20 is provided on the surface of the semiconductor substrate 241 opposite to the light incident surface, that is, on the lower surface side in the figure. The surrounding part 30 is covered from the bottom with the interlayer insulating film 262 or the like disposed on the bottom surface in the figure. Similar to the above embodiment, in this application example 1-2, the surrounding part 30 is made of a material different from that of the semiconductor substrate 241, and is made of, for example, silicon nitride (SiN), or silicon nitride containing at least one of oxygen and carbon (SiON, SiCN).

In application example 1-2 described above, the surrounding part 30 is also formed in advance when the trench 21 for the inter-pixel isolation part 20 is formed. Accordingly, as in the above embodiment, when the hard mask (for example, SiO) used at the time of forming the trench 21 is removed, the insulating film (for example, interlayer insulating film 262) covering the opposite side to the light incident surface of the semiconductor substrate 241 and the via connected to the opposite side of the light incident surface of the semiconductor substrate 241 can be prevented from being eroded by the chemical solution for removing the hard mask, thereby suppressing a decrease in yield.

### (1-3) Application Example 1-3

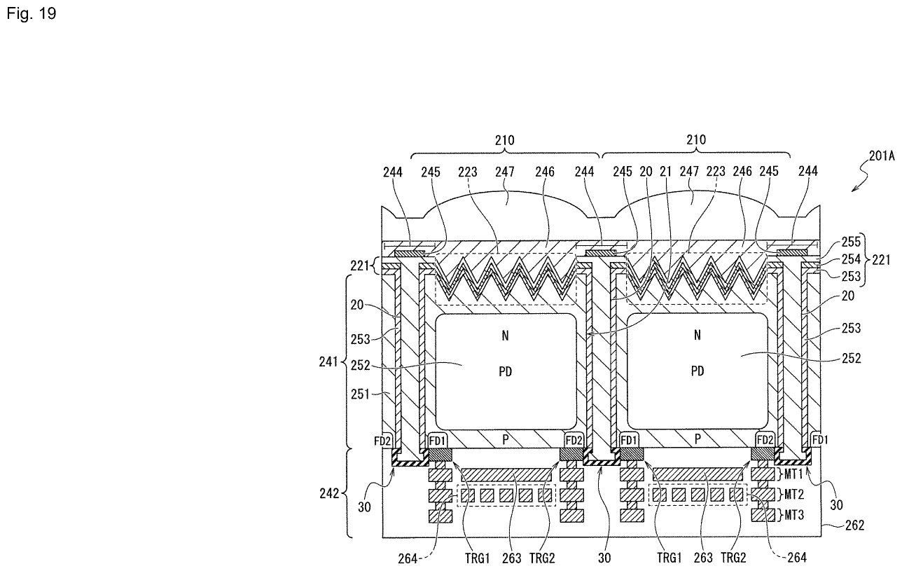

FIG. 19 is a cross-sectional view showing a configuration of a pixel array of a light-receiving element 201A according to application example 1-3 of the present disclosure. Application example 1-3 is a modified example of application example 1-2. Application example 1-3 differs from application example 1-2 in that a PD upper region 223 has a substrate interface having a moth-eye structure and an anti-reflection film 221.

In the light receiving element according to application example 1-3, the PD upper region 223 located above the photodiode PD formation region of (a P-type semiconductor region 51 of) the semiconductor substrate 241 has a moth-eye structure in which fine recesses and protrusions are formed. Further, the anti-reflection film 221 formed on the upper surface thereof is also formed in a moth-eye structure corresponding to the moth-eye structure of the PD upper region 223 of the semiconductor substrate 241. The anti-reflection film 221, like the anti-reflection film 243 (refer to FIG. 18) of application example 1-2, is formed by laminating a hafnium oxide film 253, an aluminum oxide film 254, and a silicon oxide film 255.

By forming the PD upper region 223 of the semiconductor substrate 241 in the moth-eye structure in this manner, it is possible to mitigate a sudden change in the refractive index at the substrate interface and to reduce influences of reflected light.

In application example 1-3, the inter-pixel isolation part 20 and the surrounding part 30 have the same construction as those in application example 1-2. The effects of preventing erosion of the chemical solution when removing the hard mask and suppressing a decrease in the yield by preventing the erosion are similar to those of the application example 1-2.

### (2) Application Example 2; Application to Direct ToF Type Ranging Sensor

Application example 2 is an example in which the technique of the present disclosure is applied to an imaging element (light-receiving element) constituting a ranging sensor that performs distance measurement using the direct ToF method, and an imaging device having such an imaging element.

### (2-1) Application Example 2-1

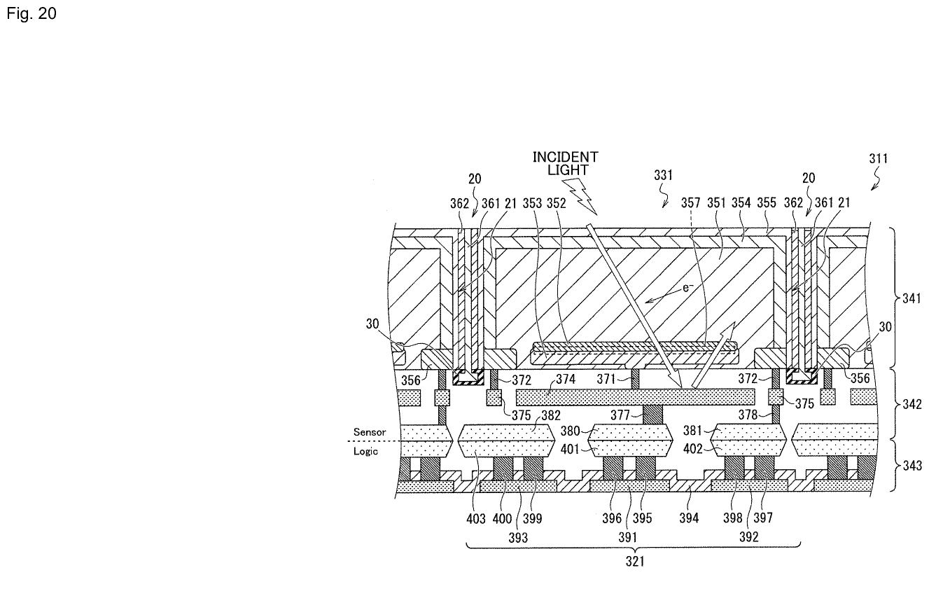

FIG. 20 is a cross-sectional view showing a configuration of a sensor chip 311 according to application example 2-1 of the present disclosure. The sensor chip 311 is an imaging element (light-receiving element) constituting a ranging sensor that performs distance measurement by the direct ToF method. The configuration of the sensor chip 311 will be described with reference to FIG. 20.

As shown in FIG. 20, the sensor chip 311 has a laminated structure in which a sensor substrate 341 (an example of a “semiconductor substrate” in the present disclosure), a sensor-side wiring layer 342, and a logic-side wiring layer 343 are laminated, a logic circuit substrate that is not shown is laminated for the logic-side wiring layer 343. For example, a bias voltage application portion, a p-type MOSFET, a CMOS inverter, and the like are formed on the logic circuit substrate. For example, the sensor chip 311 can be manufactured by a manufacturing method of forming the sensor-side wiring layer 342 on the sensor substrate 341, forming the logic-side wiring layer 343 on the logic circuit substrate, and then bonding the sensor-side wiring layer 342 and the logic-side wiring layer 343 on a bonding surface (a surface indicated by a broken line in FIG. 20).

The sensor substrate 341 is, for example, a semiconductor substrate obtained by slicing a single crystal silicon thin and has a controlled p-type or n-type impurity concentration, and a single photon avalanche diode (SPAD) element 331 is formed for each SPAD pixel 321. Further, in FIG. 20, the surface of the sensor substrate 341 facing upward serves as a light receiving surface for receiving light, and the sensor-side wiring layer 342 is laminated on the surface opposite to the light receiving surface. The light receiving surface is an example of the “second surface” in the present disclosure. The surface opposite to the light receiving surface is the “first surface” in the present disclosure.

A wiring line for supplying a voltage to be applied to the SPAD element 331, a wiring line for extracting electrons generated in the SPAD element 331 from the sensor substrate 341, and the like are formed in the sensor-side wiring layer 342 and the logic-side wiring layer 343.

The SPAD element 331 includes an N well 351, a P-type diffusion layer 352, an N-type diffusion layer 353, a hole accumulation layer 354, a pinning layer 355, and a high concentration P-type diffusion layer 356 formed in the sensor substrate 341. In addition, a depletion layer formed in a region where the P-type diffusion layer 352 and the N-type diffusion layer 353 are connected forms an avalanche multiplication region 357 in the SPAD element 331.

The N well 351 is formed by controlling the impurity concentration of the sensor substrate 341 to an n-type and forms an electric field by which electrons generated by photoelectric conversion in the SPAD element 331 are transferred to the avalanche multiplication region 357. Note that a P well may be formed by controlling the impurity concentration of the sensor substrate 341 to a p type instead of the N well 351.

The P-type diffusion layer 352 is a heavily doped P-type diffusion layer (P+ ) formed near the front surface of the sensor substrate 341 and on the rear surface side (upper side in FIG. 20) with respect to the N-type diffusion layer 353, and is formed to extend over substantially the entire surface of the SPAD element 331.

The N-type diffusion layer 353 is a heavily doped N-type diffusion layer (N+ ) formed near the front surface of the sensor substrate 341 and on the front surface side (lower side in FIG. 20) with respect to the P-type diffusion layer 352, and is formed to extend over substantially the entire surface of the SPAD element 331. In addition, the N-type diffusion layer 353 has a convex shape such that a part thereof extends to the front surface of the sensor substrate 341 in order to connect to a contact electrode 371 for supplying a negative voltage for forming the avalanche multiplication region 357.

The hole accumulation layer 354 is a P-type diffusion layer (P) that is formed to surround the side surface and the bottom surface of the N well 351, and holes are accumulated therein. In addition, the hole accumulation layer 354 is electrically connected to an anode of SPAD element 331 to allow bias adjustment. As a result, the hole concentration in the hole accumulation layer 354 is increased, and pinning including the pinning layer 355 is strengthened, thereby suppressing generation of dark current, for example.

The pinning layer 355 is a heavily doped P-type diffusion layer (P+ ) formed on the surface outside the hole accumulation layer 354 (the side surface in contact with the rear surface of the sensor substrate 341 and an insulating film 62), and suppresses generation of dark current similarly to the hole accumulation layer 354.

The high concentration P-type diffusion layer 356 is a heavily doped P-type diffusion layer (P++) formed to surround the outer periphery of the N well 351 near the front surface of the sensor substrate 341, and is used for connection to a contact electrode 372 for electrically connecting the hole accumulation layer 354 to the anode of the SPAD element 331.

The avalanche multiplication region 357 is a high electric field region formed at the interface between the P-type diffusion layer 352 and the N-type diffusion layer 353 by a high negative voltage applied to the N-type diffusion layer 353, and multiplies electrons (e−) generated by one photon incident on the SPAD element 331.

Further, in the sensor chip 311, each SPAD element 331 is isolated and separated by an inter-pixel isolation part 20 having a double structure formed of a metal film 361 and an insulating film 362 formed between adjacent SPAD elements 331. In this application example 2-1, the metal film 361 and the insulating film 362 are an example of an “isolation film” in the present disclosure. For example, the inter-pixel isolation part 20 is formed to penetrate the sensor substrate 341 from the rear surface to the front surface of the sensor substrate 341.

The metal film 361 is a film formed of a metal that reflects light (for example, tungsten or the like), and the insulating film 362 is a film having insulating properties such as SiO. For example, the inter-pixel isolation part 20 is formed by embedding the metal film 361 in the sensor substrate 341 such that the surface of the metal film 361 is covered with the insulating film 362, and the inter-pixel isolation part 20 electrically and optically isolates adjacent SPAD elements 331.

Contact electrodes 371 to 373, metal wiring lines 374 to 375, contact electrodes 377 and 378, and metal pads 380 to 382 are formed in the sensor-side wiring layer 342.

The contact electrode 371 connects the N-type diffusion layer 353 and the metal wiring line 374 and the contact electrode 372 connects the high concentration P-type diffusion layer 356 and the metal wiring line 375.

For example, the metal wiring line 374 is formed wider than the avalanche multiplication region 357 to cover at least the avalanche multiplication region 357. In addition, the metal wiring line 374 reflects light that has passed through the SPAD element 331 back to the SPAD element 331, as indicated by the hollow arrow in FIG. 20.

For example, the metal wiring line 375 is formed to overlap the high concentration P-type diffusion layer 356 to surround the periphery of the metal wiring line 374.

The contact electrode 377 connects the metal wiring line 374 and the metal pad 380. The contact electrode 378 connects the metal wiring line 375 and the metal pad 381.

The metal pads 380 to 382 are used to be electrically and mechanically bonded to metal pads 401 to 403 formed on the logic-side wiring layer 343 by the metal (Cu) that forms each of the metal pads.

Electrode pads 391 to 393, an insulating layer 394, contact electrodes 395 to 400, and the metal pads 401 to 403 are formed in the logic-side wiring layer 343.

The electrode pads 391 to 393 are used for connection with the logic circuit substrate (not illustrated) and the insulating layer 394 insulates the electrode pads 391 to 393 from each other.

The contact electrodes 395 and 396 connect the electrode pad 391 and the metal pad 401. The contact electrodes 397 and 398 connect the electrode pad 392 and the metal pad 402. The contact electrodes 399 and 400 connect the electrode pad 393 and the metal pad 403.

The metal pad 401 is bonded to the metal pad 380. The metal pad 402 is bonded to the metal pad 381. The metal pad 403 is bonded to the metal pad 382.

With such a wiring structure, the electrode pad 391 is connected to the N-type diffusion layer 353 via the contact electrodes 395 and 396, the metal pad 401, the metal pad 380, the contact electrode 377, the metal wiring line 374, and the contact electrode 371, for example. Therefore, in the SPAD pixel 321, a high negative voltage applied to the N-type diffusion layer 353 can be supplied from the logic circuit substrate to the electrode pad 391.

In addition, the electrode pad 392 is connected to the high concentration P-type diffusion layer 356 via the contact electrodes 397 and 398, the metal pad 402, the metal pad 381, the contact electrode 378, the metal wiring line 375, and the contact electrode 372. Therefore, in the SPAD pixel 321, the anode of the SPAD element 331 electrically connected to the hole accumulation layer 354 is connected to the electrode pad 392, and thus the bias for the hole accumulation layer 354 can be adjusted via the electrode pad 392.

In addition, as described above, in the SPAD pixel 321, the metal wiring line 374 is formed wider than the avalanche multiplication region 357 to cover at least the avalanche multiplication region 357, and the metal film 361 is formed to penetrate the sensor substrate 341. That is, the SPAD pixel 321 is formed to have a reflection structure in which the metal wiring line 374 and the metal film 361 surround all of the regions other than the light incident surface of the SPAD element 331. Therefore, the SPAD pixel 321 can prevent the occurrence of optical crosstalk according to the effect of reflecting light by the metal wiring line 374 and the metal film 361, and can improve the sensitivity of the SPAD element 331.

In addition, in the SPAD pixel 321, the side surface and the bottom surface of the N well 351 are surrounded by the hole accumulation layer 354, and the connection configuration in which the hole accumulation layer 354 is electrically connected to the anode of the SPAD element 331 enables bias adjustment.

The SPAD pixel 321 configured as described above prevents crosstalk from occurring and improves the sensitivity of the SPAD element 331, resulting in improved characteristics.

In addition, the surrounding part 30 surrounding an end of the inter-pixel isolation part 20 is provided on the surface of the sensor substrate 341 opposite to the light incident surface, that is, on the lower surface side in the figure. The surrounding part 30 is covered from below with the interlayer insulating film or the like of the sensor-side wiring layer 342 disposed on the lower surface in the figure. As in the above embodiment, in this application example 2-1, the surrounding part 30 is made of a material different from that of the sensor substrate 341, and is made of, for example, silicon nitride (SiN), or silicon nitride containing at least one of oxygen and carbon (SiON, SiCN).

In the above-described application example 2-1, the surrounding part 30 is formed in advance when the trench 21 for the inter-pixel isolation part 20 is formed.

Accordingly, as in the above embodiment, when the hard mask (for example, SiO) used at the time of forming the trench 21 is removed, the effect of preventing erosion of the chemical solution and suppressing a decrease in yield by preventing the erosion is obtained.

### (2-2) Application Example 2-2

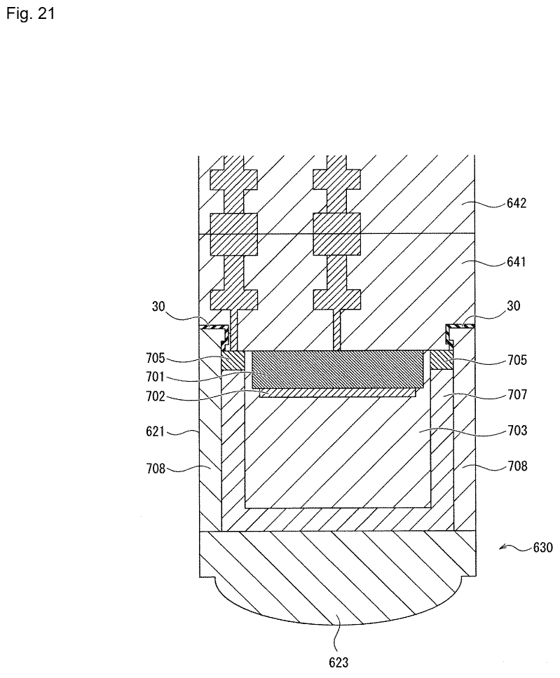

FIG. 21 is a cross-sectional view showing a configuration of a backside illumination type pixel 630 according to application example 2-2 of the present disclosure. Referring to FIG. 21 from the bottom, the pixel 630 is configured such that an avalanche photodiode (APD) 621 is laminated on an on-chip lens 623, a sensor substrate 641 (an example of the “semiconductor substrate” in the present disclosure) is laminated on the APD 621, and a circuit substrate 642 is laminated on the sensor substrate 641. The sensor substrate is made of, for example, single crystal Si (silicon).

Light is incident from the side of the on-chip lens 623 (lower side in FIG. 21) on the APD 621. In the case of the backside illumination type pixel 630, the circuit can also have a laminated structure as a circuit substrate 642 as shown in FIG. 21, the circuit may be disposed in a region outside the pixel area, and the circuit may be disposed in the same substrate.

As shown in FIG. 21, an N-type semiconductor region 701 and a P-type semiconductor region 702 in contact with the lower portion of the N-type semiconductor region 701 are formed in the APD 621. The N-type semiconductor region 701 and the P-type semiconductor region 702 are formed in a well layer 703.

The well layer 703 may be an N-type semiconductor region or a P-type semiconductor region. Further, the well layer 703 is preferably an N-type or P-type semiconductor region of low concentration of 1E14 order or less, for example. This facilitates depletion of the well layer 703 and can improve the detection efficiency called photon detection efficiency (PDE).

The P-type semiconductor region 702 forms a pn junction at the interface with the N-type semiconductor region 701. The P-type semiconductor region 702 has a multiplication region in which avalanche multiplication of carriers generated by incidence of light to be detected is performed. It is preferable that the P-type semiconductor region 702 be depleted, thereby improving the PDE.

The N-type semiconductor region 701 functions as a cathode and is connected to the circuit via a contact 704. An anode 705 for the cathode is the same layer as the N-type semiconductor region 701, and is formed between the N-type semiconductor region 701 and an isolation region 708. The anode 705 is connected to the circuit via the contact 706.

The isolation region 708 for isolating the APDs 621 from each other is formed, and a hole accumulation region 707 is formed between the isolation region 708 and the well layer 703. The hole accumulation region 707 is formed under the anode 705 and is electrically connected to the anode 705. The hole accumulation region 707 is formed between the well layer 703 and the isolation region 708. Further, the hole accumulation region 707 is also formed under the well layer 703 (on the rear surface side of the APD 621).

The hole accumulation region 707 is formed at a portion where different materials are in contact with each other. In the example shown in FIG. 21, the isolation region 708 is made of, for example, a silicon oxide film, and since the material of the isolation region 708 is different from that of the well layer 703, the hole accumulation region 707 for suppressing a dark current generated at the interface is formed.

In addition, when the APD 621 is applied to the backside illumination type, for example, as shown in FIG. 21, an on-chip lens 723 is laminated below the well layer 703 (on the side opposite to the side on which the N-type semiconductor region 701 is formed), but the hole accumulation region 707 is also formed at the interface with the well layer 703 on the side on which the on-chip lens 23 is formed. The hole accumulation region 707 can be formed as a P-type semiconductor region.

In addition, a surrounding part 30 surrounding an end of the isolation region 708 is provided on a surface side of the APD 621 opposite to the light incident surface (that is, on the side opposite to the on-chip lens 623 across the APD 621). The surrounding part 30 is covered with an interlayer insulating film or the like from the upper side in the figure. As in the above embodiment, in this application example 2-2, the surrounding part 30 is made of a material different from that of the sensor substrate 641, and is made of, for example, silicon nitride (SiN), or silicon nitride containing at least one of oxygen and carbon (SiON, SiCN).

In the above-described application example 2-2, the surrounding part 30 is also formed in advance when the trench for the isolation region 708 is formed. Accordingly, as in the above embodiments, when the hard mask (e.g., SiO) used at the time of forming the trench is removed, the effect of preventing erosion of the chemical solution and suppressing a decrease in yield by preventing the erosion is obtained.

### (3) Application Example 3; Application to CMOS Image Sensor

Application example 3 is an example of applying the technique of the present disclosure to a CMOS image sensor.

### (3-1) Application Example 3-1

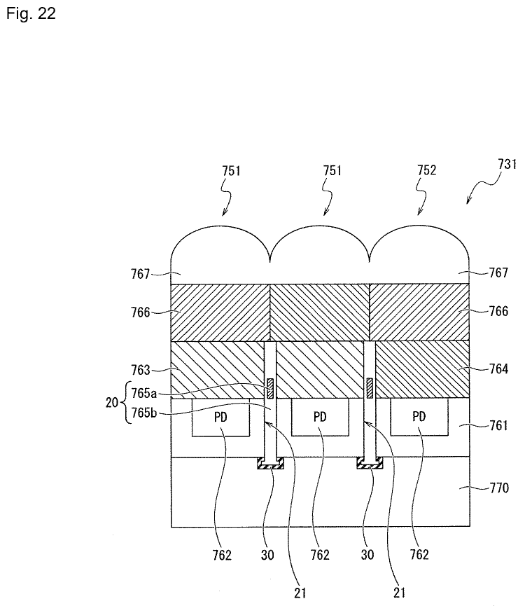

FIG. 22 is a cross-sectional view showing a configuration of a pixel in an imaging device 731 according to application example 3-1 of the present disclosure. FIG. 22 shows a cross-sectional view of a visible light pixel 751 and an infrared light pixel 752 in the imaging device 731. The visible light pixel 751 is configured as, for example, three kinds of pixels, an R pixel, a G pixel, and a B pixel.

In the visible light pixel 751, a photoelectric conversion part 762 composed of a photodiode (PD) that receives incident light and performs photoelectric conversion thereon is formed in a semiconductor substrate 761. An insulating layer (not shown) made of silicon oxide (SiO), a wiring layer (not shown) made of copper (Cu) or aluminum (Al), and the like are formed on the semiconductor substrate 761. An Infrared cut filter 763 is formed as a first optical filter layer thereon. A color filter 766 having spectral characteristics corresponding to each visible light pixel 751 is formed as a second optical filter layer on the Infrared cut filter 763. A micro-lens 767 is formed on the color filter 766.

In the infrared light pixel 752, the photoelectric conversion part 762 is formed in the semiconductor substrate 761. An insulating layer, a wiring layer, and the like (not shown) are formed on the semiconductor substrate 761, and a B (blue) color filter 764, for example, is formed as a first optical filter layer thereon. AR (red) color filter 766, for example, is formed as a second optical filter layer on the color filter 764. The micro-lens 767 is formed on the color filter 766. Both the color filters 764 and 766 are configured as color filters that transmit infrared light, and the light transmittance in the visible light region can be reduced by the combination of two layers of color filters.

In addition, each of the pixels (the visible light pixel 751 and the infrared light pixel 752) has an inter-pixel isolation part 20 that isolates the first optical filter layer for each pixel. The inter-pixel isolation part 20 is formed of a metal film 765a made of tungsten (W), aluminum (Al), or the like, and an Si oxide film 765b made of silicon oxide (SiO), silicon nitride (SiN), or the like. In the example of FIG. 22, the height of the inter-pixel isolation part 20 is set to the same height as the first optical filter layer (Infrared cut filter 763 or color filter 764).

For example, as shown in FIG. 22, a portion corresponding to a PD isolation wall in the inter-pixel isolation part 20 for isolating the photoelectric conversion part 762 from the first optical filter layer for each pixel is formed of an Si oxide film 765b made of SiO, SiN, or the like.

Further, a surrounding part 30 surrounding an end of the inter-pixel isolation part 20 is provided on the surface of the semiconductor substrate 761 opposite to the light incident surface, that is, on the lower surface side in the figure. The lower end of the inter-pixel isolation part 20 is formed of, for example, the Si oxide film 765b. The surrounding part 30 is covered from below with an interlayer insulating film 770 or the like disposed on the lower surface in the figure. As in the above embodiment, in this application example 3-1, the surrounding part 30 is made of a material different from that of the semiconductor substrate 761, and is made of, for example, silicon nitride (SiN), or silicon nitride containing at least one of oxygen and carbon (SiON, SiCN).

In the above-described application example 3-1, the surrounding part 30 is also formed in advance when the trench 21 for the inter-pixel isolation part 20 is formed. Accordingly, as in the above embodiment, when the hard mask (for example, SiO) used at the time of forming the trench 21 is removed, the effect of preventing erosion of the chemical solution and suppressing a decrease in yield by preventing the erosion is obtained.

### (3-2) Application Example 3-2

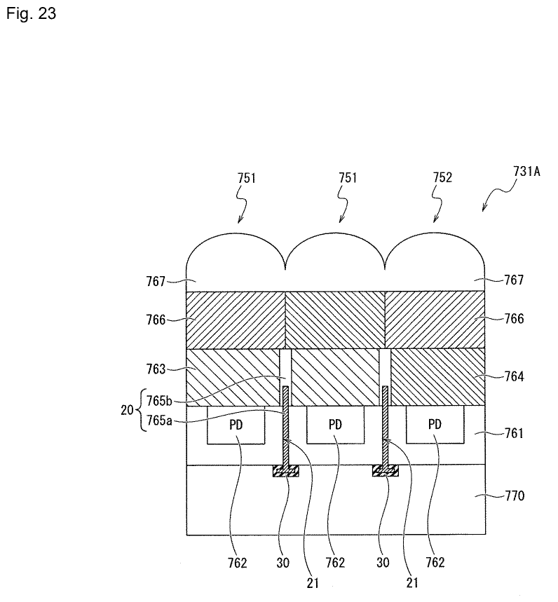

FIG. 23 is a cross-sectional view showing a configuration of a pixel array of an imaging device 731A according to application example 3-2 of the present disclosure. Application example 3-2 is a modified example of application example 3-1. Application example 3-2 differs from application example 3-1 in that the portion of the inter-pixel isolation part 20 corresponding to the PD isolation wall is formed of a metal film made of W, Al, or the like. By additionally providing the PD isolation wall for isolating the photoelectric conversion part 762 for each pixel in this manner, it is possible to more reliably suppress the occurrence of color mixture between pixels.

In the imaging device 731A according to application example 3-2, an end of the inter-pixel isolation part 20 is also surrounded by the surrounding part 30. In application example 3-2, the lower end of the inter-pixel isolation part 20 is formed of, for example, a metal film 765a. In such an aspect, the imaging device 731A, like the imaging device 731, has the effect of preventing erosion of the chemical solution at the time of removing the hard mask and suppressing a decrease in yield by preventing the erosion.

### Other Embodiments

While the present disclosure has been described above on the basis of the embodiments and modified examples, the description and figures that constitute parts of the present disclosure should not be understood as limiting the present disclosure. Various alternative embodiments, examples, and operable techniques will be apparent to those skilled in the art from the present disclosure. It is needless to say that the present technique includes various embodiments that are not described herein. At least one of various omissions, substitutions and modifications of constituent elements can be performed without departing from the gist of the embodiments and modified examples described above. Furthermore, the advantageous effects described in the present specification are merely exemplary and not intended as limiting, and other advantageous effects may be obtained.

The present disclosure can also be configured as follows.

(1)

A photodetector including:
a semiconductor substrate having a first surface, and a second surface located on a side opposite to the first surface;
a plurality of pixels provided on the semiconductor substrate and having photoelectric conversion elements;
an inter-pixel isolation part provided between one and the other of adjacent pixels among the plurality of pixels and penetrating between the first surface and the second surface of the semiconductor substrate; and
a surrounding part provided on the first surface side of the semiconductor substrate and surrounding an end of the inter-pixel isolation part,
wherein the surrounding part is made of a material different from a material of the semiconductor substrate.
   (2)

The photodetector according to the (1), wherein the semiconductor substrate is made of silicon, and
the surrounding part is made of silicon nitride or silicon nitride containing at least one of oxygen and carbon.
   (3)

The photodetector according to the (1) or (2), wherein
the surrounding part includes a bottom portion facing the end in a thickness direction of the semiconductor substrate, and
a side portion connecting the first surface and the bottom portion.
   (4)

The photodetector according to any one of the (1) to (3), including an insulating film provided on the first surface side of the semiconductor substrate and adjacent to the surrounding part from the outside of the surrounding part,
wherein the insulating film is made of a material different from the materials of the semiconductor substrate and the surrounding part.
   (5)

The photodetector according to the (4), wherein the insulating film is made of silicon oxide.

(6)

A method of manufacturing a photodetector, including:
a process of forming a first material film on a first surface side of a semiconductor substrate having a first surface and a second surface located on a side opposite to the first surface and provided with a plurality of pixels having photoelectric conversion elements, and covering a predetermined region for isolating adjacent pixels from each other among the plurality of pixels with the first material film from the first surface side;
a process of forming a second material film on a side opposite to the predetermined region with the first material film interposed between the second material film and the predetermined region;
a process of forming a third material film on a side opposite to the first material film with the second material film interposed between the third material film and the first material film, and surrounding the second material film with the first material film and the third material film;
a process of forming a mask having a shape of exposing the predetermined region and covering a region other than the predetermined region on the second surface side;
a process of forming a trench penetrating the semiconductor substrate and the first material film by etching the predetermined region exposed through the mask from the second surface side using the second material film as an etching stopper; and
a process of removing the mask by wet etching after forming the trench,
wherein
a chemical solution that easily etches the mask and the second material film and hardly etches the first material film and the third material film is used for the wet etching.
   (7)

The method of manufacturing a photodetector according to the (6), wherein each of
the mask and the second material film are made of silicon oxide, and each of the first material film and the third material film is made of silicon nitride or silicon nitride containing at least one of oxygen and carbon.
   (8)

The method of manufacturing a photodetector according to the (7), wherein the chemical solution contains hydrofluoric acid.

(9)

The method of manufacturing a photodetector according to any one of the (6) to (8), further including, before forming the first material film:
a process of forming an insulating film on the first surface side of the semiconductor substrate; and
a process of forming an opening by removing a portion of the insulating film overlapping the predetermined region in a thickness direction of the semiconductor substrate,
wherein, in the process of forming the first material film,
the first material film is formed on the insulating film to fill the opening, and
wherein, in the process of forming the second material film,
the second material film is formed in a region overlapping the opening in the thickness direction of the semiconductor substrate.
   (10)

The method of manufacturing the photodetector according to the (9), wherein the insulating film is made of silicon oxide.

(11)

The method of manufacturing a photodetector according to any one of the (6) to (10), further including a process of embedding an isolation film within the trench after removing the mask.

### REFERENCE SIGNS LIST

1, 1A, 1B-1, 1B-2, 1C, 1D-1, 1D-2, 1E-1, 1E-2, 1F-1, 1F-2 Photodetector
10, 241 Semiconductor substrate
10a Front surface
10b Rear surface
12, 151, 210 Pixel
20″ Overlap region
20 Inter-pixel isolation part
20 Predetermined region
20a End
21 Trench
22 Isolation film
23 On-chip lens
30 Surrounding part
31 Bottom portion
32 Side portion
32e Extension part
33 Space
41, 42, 43, 44, 46 Insulating film
50 Via
51, 171, 172, 173, 174, 251, 252 Semiconductor region
62 Insulating film
111 Imaging element
121 Pixel array
122 Vertical driver
123 Column processor
124 Horizontal driver
125 System controller
126 Signal processor
127 Data storage
128 Pixel driving line
129 Vertical signal line
135 Connection pad
161 Substrate
162, 247, 623, 723 On-chip lens
163 Inter-pixel light-shielding part
164 Oxide film
165 Signal extraction part
175 Isolation part
181, 262, 770 Interlayer insulating film
201, 201A Light-receiving element
221 Anti-reflection film
223 Upper region
242 Multilayered wiring layer
243 Anti-reflection film
244 Pixel boundary portion
244 Boundary portion
245 Inter-pixel light-shielding part
246 Planarization film
253 Hafnium oxide film
254 Aluminum oxide film
255 Silicon oxide film
263 Light-shielding member
264 Wiring capacitor
311 Sensor chip
321 SPAD pixel
331 SPAD element
341 Sensor substrate
342 Sensor-side wiring layer
343 Logic-side wiring layer
351 N well
352 P-type diffusion layer
353 N-type diffusion layer
354 Hole accumulation layer
355 Pinning layer
356 High concentration P-type diffusion layer
357 Avalanche multiplication region
361 Metal film
362 Insulating film
371, 372, 373, 377, 378, 395, 396, 397, 398, 399, 400 Contact electrode
374, 375 Metal wiring line
380, 381, 382, 401, 402, 403 Metal pad
391, 392, 393 Electrode pad
394 Insulating layer
621 Avalanche photodiode sensor (APD)
630 Pixel
641 Sensor substrate
642 Circuit substrate
701 N-type semiconductor region
703 Well layer
704, 706 Contact
705 Anode
707 Accumulation region
707 Hole accumulation region
708 Isolation region
731, 731A Imaging device
751 Visible light pixel
752 Infrared light pixel
761 Semiconductor substrate
762 Photoelectric conversion part
763 Infrared cut filter
764, 766 Color filter
765a, MT Metal film
765b Si oxide film
767 Micro-lens
A, B FD portion
FD1, FD2 Floating diffusion region
G32 Step portion
H11 Opening
HM Hard mask
M1, M2, M3 Mask
MF1 First material film
MF2 Second material film
MF3 Third material film
MT1 First metal film
MT2 Second metal film
MT3 Third metal film
TRG1, TRG2 Transfer transistor

1. A photodetector comprising:
a semiconductor substrate having a first surface, and a second surface located on a side opposite to the first surface;
a plurality of pixels provided on the semiconductor substrate and having photoelectric conversion elements;
an inter-pixel isolation part provided between one and the other of adjacent pixels among the plurality of pixels and penetrating between the first surface and the second surface of the semiconductor substrate; and
a surrounding part provided on the first surface side of the semiconductor substrate and surrounding an end of the inter-pixel isolation part,
wherein the surrounding part is made of a material different from a material of the semiconductor substrate.

2. The photodetector according to claim 1, wherein the semiconductor substrate is made of silicon, and
the surrounding part is made of silicon nitride or silicon nitride containing at least one of oxygen and carbon.

3. The photodetector according to claim 1, wherein
the surrounding part includes a bottom portion facing the end in a thickness direction of the semiconductor substrate, and
a side portion connecting the first surface and the bottom portion.

4. The photodetector according to claim 1, further comprising an insulating film provided on the first surface side of the semiconductor substrate and adjacent to the surrounding part from the outside of the surrounding part,
wherein the insulating film is made of a material different from the materials of the semiconductor substrate and the surrounding part.

5. The photodetector according to claim 4, wherein the insulating film is made of silicon oxide.

6. A method of manufacturing a photodetector, comprising:
a process of forming a first material film on a first surface side of a semiconductor substrate having a first surface and a second surface located on a side opposite to the first surface and provided with a plurality of pixels having photoelectric conversion elements, and covering a predetermined region for isolating adjacent pixels from each other among the plurality of pixels with the first material film from the first surface side;
a process of forming a second material film on a side opposite to the predetermined region with the first material film interposed between the second material film and the predetermined region;
a process of forming a third material film on a side opposite to the first material film with the second material film interposed between the third material film and the first material film, and surrounding the second material film with the first material film and the third material film;
a process of forming a mask having a shape of exposing the predetermined region and covering a region other than the predetermined region on the second surface side;
a process of forming a trench penetrating the semiconductor substrate and the first material film by etching the predetermined region exposed through the mask from the second surface side using the second material film as an etching stopper; and
a process of removing the mask by wet etching after forming the trench,
wherein
a chemical solution that easily etches the mask and the second material film and hardly etches the first material film and the third material film is used for the wet etching.

7. The method of manufacturing a photodetector according to claim 6, wherein each of the mask and the second material film is made of silicon oxide, and
each of the first material film and the third material film is made of silicon nitride or silicon nitride containing at least one of oxygen and carbon.

8. The method of manufacturing a photodetector according to claim 7, wherein the chemical solution contains hydrofluoric acid.

9. The method of manufacturing a photodetector according to claim 6, further comprising, before forming the first material film:
a process of forming an insulating film on the first surface side of the semiconductor substrate; and
a process of forming an opening by removing a portion of the insulating film overlapping the predetermined region in a thickness direction of the semiconductor substrate,
wherein, in the process of forming the first material film,
the first material film is formed on the insulating film to fill the opening, and in the process of forming the second material film,
the second material film is formed in a region overlapping the opening in the thickness direction of the semiconductor substrate.

10. The method of manufacturing a photodetector according to claim 9, wherein the insulating film is made of silicon oxide.

11. The method of manufacturing a photodetector according to claim 6, further comprising a process of embedding an isolation film within the trench after removing the mask.
